(19) United States
(12) Patent Application Publication
(10) Pub. No.: US 2026/0251939 A1
(43) Pub. Date: Aug. 27, 2026

(54) ARRAY SUBSTRATE, DISPLAY PANEL AND DISPLAY APPARATUS

(71) Applicants: ORDOS YUANSHENG OPTOELECTRONICS CO., LTD., Ordos (CN); BOE TECHNOLOGY GROUP CO., LTD., Beijing (CN); BEIJING BOE TECHNOLOGY DEVELOPMENT CO., LTD., Beijing (CN)

(72) Inventors: Yongqiang ZHANG, Beijing (CN); Jingyi XU, Beijing (CN); Wei LI, Beijing (CN); Xiaofeng YIN, Beijing (CN); Aiyu DING, Beijing (CN); Jingwei HOU, Beijing (CN); Peirong HUO, Beijing (CN); Feng LI, Beijing (CN); Zhi LI, Beijing (CN)

(73) Assignees: ORDOS YUANSHENG OPTOELECTRONICS CO., LTD., Ordos (CN); BOE TECHNOLOGY GROUP CO., LTD., Beijing (CN); BEIJING BOE TECHNOLOGY DEVELOPMENT CO., LTD., Beijing (CN)

(21) Appl. No.: 18/995,380

(22) PCT Filed: May 29, 2024
(86) PCT No.: PCT/CN2024/095889

§ 371 Date: Jan. 16, 2025

(30) Foreign Application Priority Data
Jun. 30, 2023 (CN) 202310796827.7

(51) Int. Cl. G02F 1/1362; G02F 1/1368; H10D 86/40; H10D 86/60

(52) U.S. Cl. CPC G02F 1/136209; G02F 1/1368; H10D 86/441; H10D 86/451; H10D 86/60

(57) ABSTRACT

At least one embodiment of the present disclosure provides an array substrate, a display panel, and a display apparatus, the array substrate includes: a semiconductor layer and a light-shielding layer, the semiconductor layer includes a first branch portion, a second branch portion, a connection portion; the first branch portion includes a first channel region, the second branch portion includes a second channel region; a first via hole structure is on a side of the first branch portion away from the base substrate, an orthographic projection of the first via hole structure on the base substrate is within an orthographic projection of an end of the first branch portion away from the connection portion on the base substrate; an orthographic projection of the light-shielding layer on the base substrate at least covers orthographic projections of the first channel region and the first via hole structure on the base substrate.

The present application claims priority to Chinese Patent Application No. 202310796827.7 filed on Jun. 30, 2023, the disclosure of which is incorporated herein by reference in its entirety as a part of this application.

### TECHNICAL FIELD

Embodiments of the present disclosure relate to an array substrate, a display panel, and a display apparatus.

### BACKGROUND

Low-Temperature Polycrystalline Silicon Thin film Transistor (LTPS TFT) technology has become increasingly mature. Compared with an amorphous silicon thin film transistor and a metal oxide thin film transistor, low-temperature polycrystalline silicon thin film transistor has a higher carrier mobility, which can enhance the driving ability of a display apparatus using the low-temperature polycrystalline silicon thin film transistor to reduce power consumption. The current structure of the low-temperature polysilicon thin film transistor is a top gate structure. When the low-temperature polysilicon thin film transistor is used for a liquid crystal display panel, it is necessary to design a light-shielding layer to completely cover a channel region, otherwise the phenomenon of light leakage would occur in a channel region of the low-temperature polysilicon.

### SUMMARY

At least one embodiment of the present disclosure provides an array substrate, a display panel, and a display apparatus. In the array substrate, the orthographic projection of a light-shielding layer on a base substrate at least covers the orthographic projections of a first channel region and a first via hole structure on the base substrate. Leakage current of a display panel formed later can be reduced by the array substrate by adjusting design of the light-shielding layer, so that the holding capability of the pixel capacitance is improved, thereby the problem of flicker at a low frequency can be alleviated, and an aperture ratio of the display panel formed later can also be ensured.

At least one embodiment of the present disclosure provides an array substrate, the array substrate includes: a base substrate, and a semiconductor layer and a light-shielding layer that are stacked on the base substrate, in which the semiconductor layer comprises a first branch portion and a second branch portion that are provided opposite to each other, and a connection portion connecting the first branch portion and the second branch portion; the first branch portion comprises a first channel region, and the second branch portion comprises a second channel region; a first via hole structure is provided on a side of the first branch portion away from the base substrate, and an orthographic projection of the first via hole structure on the base substrate is located within an orthographic projection of an end of the first branch portion away from the connection portion on the base substrate; and an orthographic projection of the light-shielding layer on the base substrate at least covers orthographic projections of the first channel region and the first via hole structure on the base substrate.

For example, in the array substrate provided by at least one embodiment of the present disclosure, a second via hole structure is provided on a side of the second branch portion away from the base substrate, an orthographic projection of the second via hole structure on the base substrate is located within an orthographic projection of an end of the second branch portion away from the connection portion on the base substrate, and a minimum distance between the second via hole structure and the connection portion is greater than or equal to a minimum distance between the first via hole structure and the connection portion.

For example, in the array substrate provided by at least one embodiment of the present disclosure, the orthographic projection of the second via hole structure on the base substrate is located outside the orthographic projection of the light-shielding layer on the base substrate.

For example, in the array substrate provided by at least one embodiment of the present disclosure, a plurality of thin film transistors are provided on the base substrate, portions of the light-shielding layer corresponding to different thin film transistors are spaced apart from each other, and portions of the light-shielding layer corresponding to the first channel region and the second channel region of a same thin film transistor are in an integral structure.

For example, in the array substrate provided by at least one embodiment of the present disclosure, both the first branch portion and the second branch portion extend in a first direction, the connection portion extends in a second direction that intersects the first direction, the first branch portion, the second branch portion, and the connection portion surround to form an opening region, at least a part of the opening region is covered by the light-shielding layer.

For example, the array substrate provided by at least one embodiment of the present disclosure further includes a first metal layer provided on a side of the semiconductor layer away from the base substrate, the first metal layer comprises a gate line extending in the second direction, the gate line comprises a first gate electrode and a second gate electrode, an orthographic projection of the first gate electrode on the base substrate overlaps with an orthographic projection of the first channel region on the base substrate, and an orthographic projection of the second gate electrode on the base substrate overlaps with an orthographic projection of the second channel region on the base substrate.

For example, in the array substrate provided by at least one embodiment of the present disclosure, there is a gap between the light-shielding layer and the connection portion in the first direction.

For example, in the array substrate provided by at least one embodiment of the present disclosure, a plurality of thin film transistors are provided on the base substrate, portions of the light-shielding layer corresponding to different thin film transistors are spaced apart from each other, portions of the light-shielding layer corresponding to the first channel region and the second channel region of a same thin film transistor are a first sub light-shielding portion and a second sub light-shielding portion, respectively, and the first sub light-shielding portion and the second sub light-shielding portion are spaced apart from each other.

For example, in the array substrate provided by at least one embodiment of the present disclosure, the orthographic projection of the first via hole structure on the base substrate is located within an orthographic projection of the first sub light-shielding portion on the base substrate, and an orthographic projection of a second via hole structure on the base substrate is located outside an orthographic projection of the second sub light-shielding portion on the base substrate.

At least one embodiment of the present disclosure further provides a display panel, the display panel includes a first substrate and a second substrate that are provided opposite to each other, in which the first substrate comprises a base substrate, and a semiconductor layer and a light-shielding layer that are stacked on the base substrate; the second substrate comprises a black matrix; the semiconductor layer comprises a first branch portion and a second branch portion that are provided opposite to each other, and a connection portion connecting the first branch portion and the second branch portion; the first branch portion comprises a first channel region, and the second branch portion comprises a second channel region; a first via hole structure is provided on a side of the first branch portion away from the base substrate, and an orthographic projection of the first via hole structure on the base substrate is located within an orthographic projection of an end of the first branch portion away from the connection portion on the base substrate; and an orthographic projection of the light-shielding layer on the base substrate is located within an orthographic projection of the black matrix on the base substrate, and at least covers the orthographic projections of the first channel region and the first via hole structure on the base substrate.

For example, in the display panel provided by at least one embodiment of the present disclosure, an end of the second branch portion away from the connection portion corresponds to a second via hole structure, and the second via hole structure is farther away from the connection portion relative to the first via hole structure.

For example, in the display panel provided by at least one embodiment of the present disclosure, a material of the light-shielding layer comprises a conductive metal, the orthographic projection of the second via hole structure on the base substrate is covered by the orthographic projection of the black matrix on the base substrate, and the orthographic projection of the second via hole structure on the base substrate is located outside the orthographic projection of the light-shielding layer on the base substrate.

For example, in the display panel provided by at least one embodiment of the present disclosure, a plurality of thin film transistors are provided on the first substrate, portions of the light-shielding layer corresponding to different thin film transistors are spaced apart from each other, and portions of the light-shielding layer corresponding to the first channel region and the second channel region of a same thin film transistor are in an integral structure.

For example, in the display panel provided by at least one embodiment of the present disclosure, both the first branch portion and the second branch portion extend in a first direction, the connection portion extends in a second direction that intersects with the first direction, and the first branch portion, the second branch portion, and the connection portion surround to form an opening region, at least a part of the opening region is covered by the light-shielding layer.

For example, in the display panel provided by at least one embodiment of the present disclosure, the first substrate further comprises a first metal layer provided on a side of the semiconductor layer away from the base substrate, the first metal layer comprises a gate line extending in the second direction, and the gate line comprises a first gate electrode and a second gate electrode, an orthographic projection of the first gate electrode on the base substrate overlaps with an orthographic projection of the first channel region on the base substrate, and an orthographic projection of the second gate electrode on the base substrate overlaps with an orthographic projection of the second channel region on the base substrate.

For example, in the display panel provided by at least one embodiment of the present disclosure, the orthographic projection of the first gate electrode on the base substrate is within the orthographic projection of the black matrix on the base substrate, and the orthographic projection of the second gate electrode on the base substrate is within the orthographic projection of the black matrix on the base substrate.

For example, in the display panel provided by at least one embodiment of the present disclosure, there is a gap between the light-shielding layer and the connection portion in the first direction.

For example, in the display panel provided by at least one embodiment of the present disclosure, an orthographic projection of an edge of the light-shielding layer corresponding to a portion of the first branching portion close to the connection portion on the base substrate overlaps with an orthographic projection of an edge of the black matrix corresponding to a portion of the first branching portion close to the connection portion on the base substrate.

For example, in the display panel provided by at least one embodiment of the present disclosure, an orthographic projection of an edge of the light-shielding layer corresponding to a portion of the first branching portion farthest away from the connection portion on the base substrate overlaps with an orthographic projection of an edge of the black matrix corresponding to a portion of the first branching portion farthest away from the connection portion on the base substrate.

For example, in the display panel provided by at least one embodiment of the present disclosure, an orthographic projection of an edge of the light-shielding layer away from the connection portion on the base substrate comprises a first portion located on a side of the first via hole structure away from the connection portion and a second portion located on a side of the second via hole structure away from the connection portion, and an orthographic projection of the second portion on the base substrate is located within an orthographic projection of an edge of the black matrix farthest away from the second via hole structure on the base substrate.

For example, in the display panel provided by at least one embodiment of the present disclosure, a plurality of thin film transistors are disposed on the first substrate, portions of the light-shielding layer corresponding to different thin film transistors are spaced apart from each other, portions of the light-shielding layer corresponding to the first channel region and the second channel region of a same thin film transistor are a first sub light-shielding portion and a second sub light-shielding portion, respectively, and the first sub light-shielding portion and the second sub light-shielding portion are spaced apart from each other.

For example, in the display panel provided by at least one embodiment of the present disclosure, the orthographic projection of the first via hole structure on the base substrate is located within an orthographic projection of the first sub light-shielding portion on the base substrate, and an orthographic projection of a second via hole structure on the base substrate is located outside the orthographic projection of the second sub light-shielding portion on the base substrate.

For example, in the display panel provided by at least one embodiment of the present disclosure, an end of the second branch portion away from the connection portion corresponds to a second via hole structure, and a maximum distance between the second via hole structure and the connection portion is equal to a maximum distance between the first via hole structure and the connection portion.

For example, in the display panel provided by at least one embodiment of the present disclosure, a material of the light-shielding layer comprises a non-conductive light shielding material, an orthographic projection of the second via hole structure on the base substrate is covered by both the orthographic projection of the black matrix on the base substrate and the orthographic projection of the light-shielding layer on the base substrate.

For example, in the display panel provided by at least one embodiment of the present disclosure, a plurality of thin film transistors are provided on the first substrate, portions of the light-shielding layer corresponding to different thin film transistors are spaced apart from each other, and portions of the light-shielding layer corresponding to the first channel region and the second channel region of a same thin film transistor are in an integral structure or are a structure in which they are spaced apart from each other.

At least one embodiment of the present disclosure further provides a display apparatus, the display apparatus includes the array substrate in any one of the above-mentioned embodiments or the display panel in any one of the above-mentioned embodiments.

### BRIEF DESCRIPTION OF DRAWINGS

In order to explain the technical solution of the embodiments of the present disclosure more clearly, the attached drawings of the embodiments will be briefly introduced below. Obviously, the attached drawings in the following description only relate to some embodiments of the present disclosure, and are not limited to the present disclosure.

FIG. 1 is a schematic diagram of a planar structure of a thin film transistor;

FIG. 2 is a schematic diagram of a cross-sectional structure of an array substrate;

FIG. 3 is a schematic diagram of a cross-sectional structure of the thin film transistor in FIG. 1;

FIG. 4 is a schematic diagram of a planar structure of an array substrate and a black matrix provided by at least one embodiment of the present disclosure;

FIG. 5 is a schematic diagram of a stacked structure of an array substrate provided by at least one embodiment of the present disclosure;

FIG. 6 is a schematic diagram of a stacked structure of still another array substrate provided by at least one embodiment of the present disclosure;

FIG. 7 is a schematic diagram of a stacked structure of yet another array substrate provided by at least one embodiment of the present disclosure;

FIG. 8 is a schematic diagram of a cross-sectional structure of the array substrate in FIG. 7;

FIG. 9 is a schematic diagram of a planar structure of yet another array substrate provided by at least one embodiment of the present disclosure;

FIG. 10 is a schematic diagram of a cross-sectional structure of the array substrate shown in FIG. 9;

FIG. 11 is a schematic diagram of a planar structure of yet another array substrate provided by at least one embodiment of the present disclosure;

FIG. 12 is a schematic diagram of a cross-sectional structure of the array substrate shown in FIG. 11;

FIG. 13 is a schematic diagram of a planar structure of yet another array substrate provided by at least one embodiment of the present disclosure;

FIG. 14 is a schematic diagram of a cross-sectional structure of the array substrate shown in FIG. 13;

FIG. 15 is a schematic diagram of a stacked structure of yet another array substrate provided by at least one embodiment of the present disclosure;

FIG. 16 is a schematic diagram of a stacked structure of yet another array substrate provided by at least one embodiment of the present disclosure;

FIG. 17 is a schematic diagram of a stacked structure of yet another array substrate provided by at least one embodiment of the present disclosure;

FIG. 18 is a schematic diagram of a cross-sectional structure of a display panel provided by at least one embodiment of the present disclosure;

FIG. 19 is a schematic diagram of a planar structure of a display panel provided by at least one embodiment of the present disclosure;

FIG. 20 is a schematic diagram of a cross-sectional structure of a first substrate provided by at least one embodiment of the present disclosure;

FIG. 21 is a schematic diagram of a planar structure of another display panel provided by at least one embodiment of the present disclosure;

FIG. 22 is a schematic diagram of a cross-sectional structure of the first substrate in FIG. 21;

FIG. 23 is a schematic diagram of a planar structure of yet another display panel provided by at least one embodiment of the present disclosure;

FIG. 24 is a schematic diagram of a cross-sectional structure of the first substrate in FIG. 23;

FIG. 25 is a schematic diagram of a planar structure of yet another display panel provided by at least one embodiment of the present disclosure;

FIG. 26 is a schematic diagram of a cross-sectional structure of the first substrate in FIG. 25;

FIG. 27 is a schematic diagram of a planar structure of yet another display panel provided by at least one embodiment of the present disclosure;

FIG. 28 is a schematic diagram of a cross-sectional structure of the first substrate in FIG. 27;

FIG. 29 is a schematic diagram of a planar structure of yet another display panel provided by at least one embodiment of the present disclosure;

FIG. 30 is a schematic diagram of a cross-sectional structure of the first substrate shown in FIG. 29;

FIG. 31 is a schematic diagram of a planar structure of yet another display panel provided by at least one embodiment of the present disclosure;

FIG. 32 is a schematic diagram of a cross-sectional structure of the first substrate shown in FIG. 31;

FIG. 33 is a schematic diagram of a planar structure of yet another display panel provided by at least one embodiment of the present disclosure;

FIG. 34 is a schematic diagram of a stacked structure of yet another display panel provided by at least one embodiment of the present disclosure;

FIG. 35 is a block diagram of a display panel provided by at least one embodiment of the present disclosure; and

FIG. 36 is a block diagram of a display apparatus provided by at least one embodiment of the present disclosure.

### DETAILED DESCRIPTION

In order to make the purpose, technical solution and advantages of the embodiments of the present disclosure clear, the technical solution of the embodiment of the present disclosure will be described clearly and completely with the accompanying drawings of specific embodiments of the present disclosure. It should be noted that the described embodiment is a part of the embodiment of the present disclosure, not the whole embodiment. Based on the described embodiments of the present disclosure, all other embodiments obtained by ordinary people in the field without creative labor belong to the scope of protection of the present disclosure.

Unless otherwise defined, technical terms or scientific terms used in the present disclosure shall have their ordinary meanings as understood by people with ordinary skills in the field to which the present disclosure belongs. The terms “first”, “second” and the like used in the present disclosure do not indicate any order, quantity or importance, but are only used to distinguish different components. Similar words such as “including” or “containing” refer to that the elements or objects appearing before the word cover the elements or objects listed after the word and their equivalents, without excluding other elements or objects. Similar words such as “connected” or “connected” are not limited to physical or mechanical connection, but can include electrical connection, whether direct or indirect. “Up”, “Down”, “Left” and “Right” are only used to indicate the relative positional relationship. When the absolute position of the described object changes, the relative positional relationship may also change accordingly.

Unless otherwise defined, the features such as “parallel”, “vertical” and “identical” used in the embodiments of the present disclosure all include cases such as “parallel”, “vertical” and “identical” in a strict sense, and cases such as “approximately parallel”, “approximately vertical” and “approximately identical” contain certain errors. For example, the above-mentioned “roughly” can refer to that the difference of the compared objects is within 10% or 5% of the average value of the compared objects. When the number of one component or element is not specified in the following of the embodiment of the present disclosure, it refers to that the component or element can be one or more, or can be understood as at least one. “At least one” refers to one or more, and “a plurality of” refers to at least two. “Arranged in the same layer” in the embodiment of the present disclosure refers to the relationship between a plurality of film layers formed by the same material after the same step (for example, one-step patterning process). The “same layer” here does not always mean that the thicknesses of the plurality of film layers are the same or the heights of the plurality of film layers in cross section are the same.

Currently, low power consumption is increasingly required for mobile devices such as mobile phones, tablet computers and notebook computers. For a display panel, reducing refresh rate of the display panel has become the main method to reduce its power consumption. When the display panel is operated at a low refresh rate, holding time of a pixel capacitance is prolonged. When leakage current (abbreviated as I_{off}) of a thin film transistor is large, holding ability of the pixel capacitance is reduced, and voltage difference between a pixel electrode and a common electrode is reduced, thereby causing brightness of the display panel to be attenuated, further causing the problem of flicker of the pixel to be aggravated, and at the same time, optical effect such as afterimage is deteriorated due to aggravation of the leakage current.

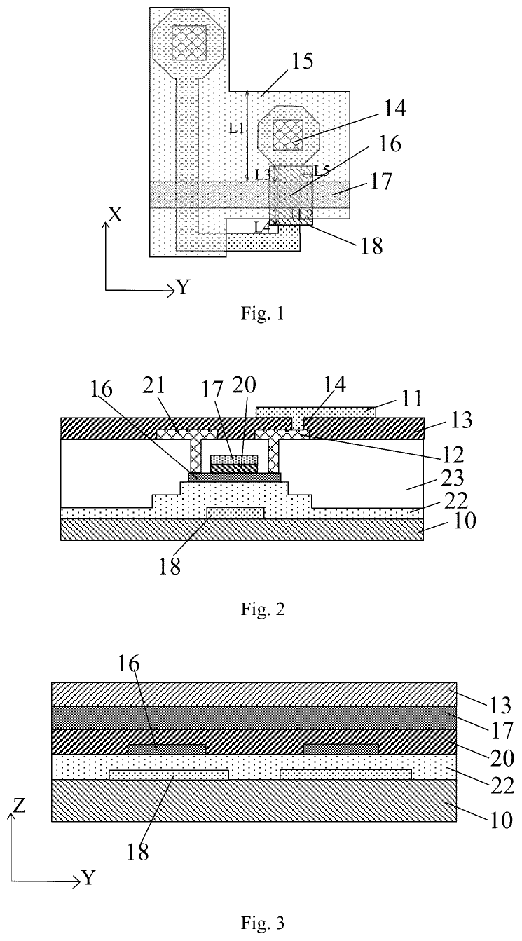

For example, FIG. 1 is a schematic diagram of a planar structure of a thin film transistor, and FIG. 2 is a schematic diagram of a cross-sectional structure of an array substrate. In combination with FIG. 1 and FIG. 2, an interlayer insulating layer 13 is provided between a pixel electrode 11 and a first source/drain electrode 12 of the thin film transistor, and a first via hole structure 14 is provided in the interlayer insulating layer 13. In order to prevent light leakage from the first via hole structure 14, a black matrix 15 (not shown in FIG. 2) needs to be provided to shield the first via hole structure 14. In the first direction X, in the right portion of the black matrix 15 corresponding to the first via hole structure 14, the length L1 of the portion where the upper side of the channel region 16 (the upper side of the region covered by the gate line 17) is shielded by the black matrix 15 is greater than the length L2 of the portion where the lower side of the channel region 16 (the lower side of the region covered by the gate line 17) is shielded by the black matrix 15. Thus, the areas on the two sides of the channel region 16 where it is shielded by the black matrix 15 in the first direction X are not consistent. Specifically, the area of the upper side of the channel region 16 where it is shielded by the black matrix 15 is larger than that of the lower side of the channel region 16 where it is shielded by the black matrix 15. Backlight is incident from a side where the low-temperature polycrystalline silicon thin film transistor is located. Under certain illumination conditions, photo-generated carriers will be excited in the channel region 16, resulting in an increase in the leakage current (I_{off}) of the thin film transistor under illumination conditions. That is, the illumination intensity is positively correlated with the leakage current I_{off} of the thin film transistor. A light-shielding layer 18 is provided on a side of the channel region 16 close to the base substrate 10. Light received by the channel region 16 can be reduced by the light-shielding layer 18, thereby leakage current under light conditions can be reduced. A first insulating layer 22 is provided between the light-shielding layer 18 and the channel region 16. A passivation layer 23 is provided between the first insulating layer 22 and the first source/drain electrode 12. A second source/drain electrode 21 and the first source/drain electrode 12 are provided opposite to each other. A gate electrode and a gate insulating layer 20 are formed in the gap between the second source/drain electrode 21 and the first source/drain electrode 12. The display panel displays by way of line scanning. A pixel is charged only for a few microseconds within one frame, and remains in the voltage holding stage for the rest of the time. Under ideal conditions, pixel voltage always maintains at the set voltage, but due to existence of leakage current in the thin film transistor, there will be a voltage attenuation in the voltage holding stage. Degree of the voltage attenuation is positively correlated with the leakage current I_{off} and voltage holding time of the thin film transistor. Moreover, the formula for leakage current voltage drop is ΔV=I_{off}*Thold/Cst. When the display panel displays in a low frequency, under the premise that frame time is increased (16.7 ms for a refresh frequency of 60 Hz, and 66.7 ms for a refresh frequency of 15 Hz), holding time of the pixel voltage is increased, and leakage current speed is the same, the voltage attenuation due to leakage current will increase at a low refresh frequency, luminance attenuation of the pixel will increase, thereby the problem of flicker will deteriorate.

For example, FIG. 3 is a schematic diagram of a cross-sectional structure of the thin film transistor in FIG. 1. As shown in FIG. 3, two channel regions 16 are shielded by two spaced light-shielding layers 18, respectively. The entirety of each channel region 16 is shielded by a corresponding light-shielding layer 18, and two adjacent light-shielding layers 18 are symmetrically provided. For example, as shown in FIG. 1, in one embodiment, in the first direction X, a shielding length L3 of the light-shielding layer 18 at the upper side of the gate line 17 is 2.05 microns, and a shielding length L4 at the lower side of the gate line 17 is also 2.05 microns. A part of the light-shielding layer 18 at the lower side of the gate line 17 has exceeded the region shielded by the black matrix 15 and entered the opening region, which may result in a decrease in the aperture ratio of the pixels of the display panel to be formed later. For example, compared with the case where the light-shielding layer 18 does not enter the opening region, the aperture ratio of the pixel will be decreased by 0.8%. Two gate electrodes of a thin film transistor with a double gate structure are shielded by the light-shielding layer 18 separately, so that a space region between the two channel regions 16 is not shielded by the light-shielding layer 18. For each channel region 16, the distance L5 where the space region other than the channel region 16 is shielded by the light-shielding layer 18 in a second direction Y perpendicular to the first direction X is small. For example, in one embodiment, the distance L5 is only 1.5 microns in size. The length L3 where the space region shielded by the light-shielding layer 18 at the upper side of the gate line 17 in the first direction X is 2.05 microns. The length L3 is also small, resulting in a larger leakage current (I_{off}) of the thin film transistor, which has a large influence on light efficiency such as flicker at a low refresh frequency.

It should be noted that in the cross-sectional structure shown in FIG. 3, a third direction Z is perpendicular to the plane in which the first direction X and the second direction Y are located. That is, the third direction Z is a direction perpendicular to the main surface of the base substrate 10.

The inventors of the present disclosure have noticed that, by shielding the channel regions of the corresponding two gate electrodes of the thin film transistor with a whole light-shielding layer or separately provided light-shielding layers with a large area, and increasing the area where a side of the first source/drain electrode connected to the pixel electrode is shielded by the light-shielding layer, that is, shielding the first via hole structure in the interlayer insulating layer with the light-shielding layer, occurrence of the leakage current phenomenon of the display panel formed later can be reduced.

At least one embodiment of the present disclosure provides an array substrate, the array substrate includes a base substrate, and a semiconductor layer and a light-shielding layer that are stacked on the base substrate, in which the semiconductor layer comprises a first branch portion and a second branch portion that are provided opposite to each other, and a connection portion connecting the first branch portion and the second branch portion; the first branch portion comprises a first channel region, and the second branch portion comprises a second channel region; a first via hole structure is provided on a side of the first branch portion away from the base substrate, and an orthographic projection of the first via hole structure on the base substrate is located within an orthographic projection of an end of the first branch portion away from the connection portion on the base substrate; and an orthographic projection of the light-shielding layer on the base substrate at least covers orthographic projections of the first channel region and the first via hole structure on the base substrate. Leakage current of a display panel formed later can be reduced by the array substrate by adjusting design of the light-shielding layer, so that holding capability of pixel capacitance is improved, thereby the problem of flicker at a low frequency can be alleviated, and aperture ratio of the display panel formed later can also be ensured.

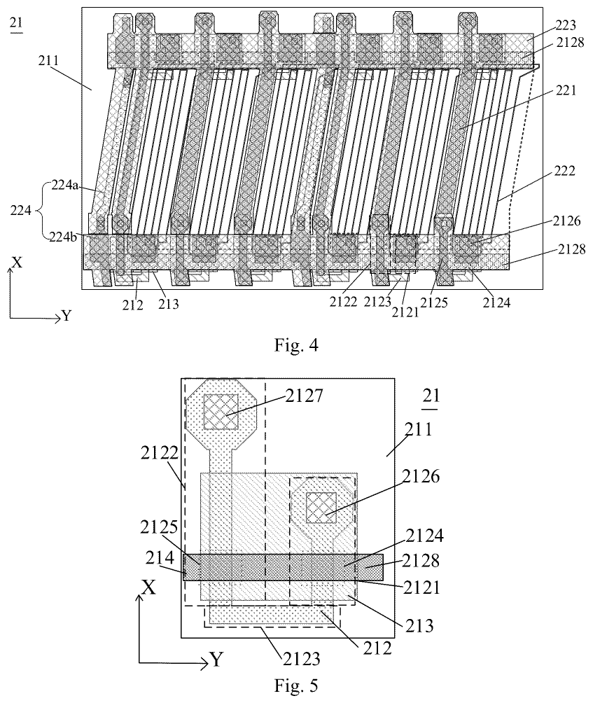

For example, FIG. 4 is a schematic diagram of a planar structure of an array substrate and a black matrix provided by at least one embodiment of the present disclosure. As shown in FIG. 4, the array substrate 21 comprises a base substrate 211, and a semiconductor layer 212 and a light-shielding layer 213 that are stacked on the base substrate 211. The semiconductor layer 212 comprises a first branch portion 2121 and a second branch portion 2122 that are provided opposite to each other, and a connection portion 2123 connecting the first branch portion 2121 and the second branch portion 2122. The first branch portion 2121 comprises a first channel region 2124, and the second branch portion 2122 comprises a second channel region 2125. The first branch portion 2121 has a first via hole structure 2126 on a side of the first branch portion 2121 away from the base substrate 211, and the orthographic projection of the first via hole structure 2126 on the base substrate 211 is located within the orthographic projection of an end of the first branch portion 2121 away from the connection portion 2123 on the base substrate 211. The orthographic projection of the light-shielding layer 213 on the base substrate 211 at least covers the orthographic projections of the first channel region 2124 and the first via hole structure 2126 on the base substrate 211. Leakage current of a display panel formed later can be reduced by the array substrate 21 by adjusting design of the light-shielding layer 213, so that the holding capability of pixel capacitance is improved, thereby the problem of flicker at a low frequency can be alleviated, and the aperture ratio of the display panel formed later can also be ensured.

It should be noted that the semiconductor layer is a state in the process of manufacturing the array substrate, and there are other subsequent processes to make part of the semiconductor region conductive. That is, after the gate electrode and gate line mentioned are formed later, there is also a heavily-doping step to turn the portion of the semiconductor layer outside the region covered by the gate electrode into a conductor, so that the channel region can be shielded by the gate electrode. Thus, the semiconductor layer located below the gate line corresponds to the channel region, and the conductive portion corresponds to the first source/drain electrode and the second source/drain electrode.

For example, as shown in FIG. 4, two channel regions, i.e., the first channel region 2124 and the second channel region 2125, are shown in the array substrate 21. An end (a first source/drain electrode) of the first branch portion 2121 that corresponds to the first via hole structure 2126 is electrically connected to the pixel electrode 222 through the first via hole structure 2126, and an end (a second source/drain electrode) of the second branch portion 2122 is connected to the data line 221. The intersection of the data line 221 and the gate line 2128 defines a pixel region, in which the pixel electrode 222 is provided.

It should be noted that the black matrix 223 is also shown in FIG. 4 to show the positional relationship between the light-shielding layer, the semiconductor layer, and the like on the array substrate and the black matrix. The orthographic projections of the data line 221, the gate line 2128, the light-shielding layer 213, the first branching portion 2121, the second branching portion 2122, and the lower-right corner portion of the connection portion 2123 on the base substrate 211 are covered by the orthographic projection of the black matrix 223 on the base substrate 211. However, the black matrix 223 is not mentioned when describing the array substrate.

For example, as shown in FIG. 4, the array substrate 21 further comprises a touch signal line 224. The touch signal line 224 comprises a first portion 224a and a second portion 224b provided parallel to the data line 221. The orthographic projection of the touch signal line 224 on the base substrate 211 is also covered by the orthographic projection of the black matrix 223 on the base substrate 211.

For example, FIG. 5 is a schematic diagram of a stacked structure of an array substrate provided by at least one embodiment of the present disclosure. As shown in FIG. 5, the array substrate 21 comprises a base substrate 211, and a semiconductor layer 212 and a light-shielding layer 213 that are stacked on the base substrate 211. The semiconductor layer 212 comprises a first branch portion 2121 and a second branch portion 2122 that are provided opposite to each other, and a connection portion 2123 connecting the first branch portion 2121 and the second branch portion 2122. The first branch portion 2121 comprises a first channel region 2124, and the second branch portion 2122 comprises a second channel region 2125. The first branch portion 2121 has a first via hole structure 2126 on a side of the first branch portion 2121 away from the base substrate 211, and the orthographic projection of the first via hole structure 2126 on the base substrate 211 is located within the orthographic projection of an end of the first branch portion 2121 away from the connection portion 2123 on the base substrate 211. The orthographic projection of the light-shielding layer 213 on the base substrate 211 at least covers the orthographic projections of the first channel region 2124 and the first via hole structure 2126 on the base substrate 211. Leakage current of a display panel formed later can be reduced by the array substrate 21 by adjusting the design of the light-shielding layer 213, so that the holding capability of pixel capacitance is improved, thereby the problem of flicker at a low frequency can be alleviated, and the aperture ratio of the display panel formed later can also be ensured.

For example, as shown in FIG. 5, the second branch portion 2122 has a second via hole structure 2127 on a side of the second branch portion 2122 away from the base substrate 211, and an orthographic projection of the second via hole structure 2127 on the base substrate 211 is located within the orthographic projection of an end of the second branch portion 2122 away from the connection portion 2123 on the base substrate 211. A minimum distance between the second via hole structure 2127 and the connection portion 2123 is greater than a minimum distance between the first via hole structure 2126 and the connection portion 2123. That is, relative to the first via hole structure 2126, the second via hole structure 2127 is farther away from the connection portion 2123. In other embodiments, the minimum distance between the second via hole structure 2127 and the connection portion 2123 may be equal to the minimum distance between the first via hole structure 2126 and the connection portion 2123.

For example, as shown in FIG. 5, the orthographic projection of the second via hole structure 2127 on the base substrate 211 is located outside the orthographic projection of the light-shielding layer 213 on the base substrate 211. That is, the second via hole structure 2127 is not covered by the light-shielding layer 213.

For example, in one embodiment, a plurality of thin film transistors are provided on the base substrate 211. Portions of the light-shielding layer 213 corresponding to different thin film transistors are spaced apart from each other, and portions of the light-shielding layer 213 corresponding to the first channel region 2124 and the second channel region 2125 of the same thin film transistor are in an integral structure. That is, in addition to the first channel region 2124 and the second channel region 2125, the portion between the first channel region 2124 and the second channel region 2125 is also covered by the light-shielding layer 213.

For example, as shown in FIG. 5, both the first branch portion 2121 and the second branch portion 2122 extend in a first direction X, and the connection portion 2123 extends in a second direction Y that intersects the first direction X. The first branch portion 2121, the second branch portion 2122, and the connection portion 2123 surround to form an opening region, at least a part of the opening region is covered by the light-shielding layer 213.

For example, in one embodiment, the first direction X and the second direction Y are perpendicular to each other.

For example, as shown in FIG. 5, the array substrate 21 further comprises a first metal layer 214 provided on a side of the semiconductor layer 212 away from the base substrate 211. The first metal layer 214 comprises a gate line 2128 extending in the second direction Y. The orthographic projection of the gate line 2128 on the base substrate 211 overlaps with the orthographic projection of the first channel region 2124 on the base substrate 211 and the orthographic projection of the second channel region 2125 on the base substrate 211.

For example, as shown in FIG. 5, there is a gap between the light-shielding layer 213 and the connection portion 2123 in the first direction X. That is, the lower edge of the light-shielding layer 213 is located above the upper edge of the connection portion 2123.

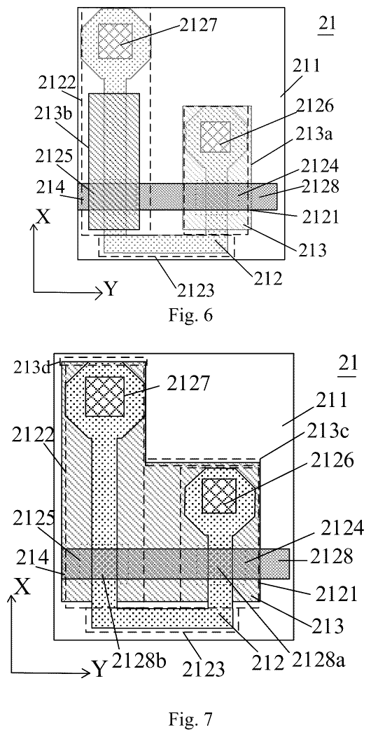

For example, FIG. 6 is a schematic diagram of a stacked structure of still another array substrate provided by at least one embodiment of the present disclosure. In one embodiment, a plurality of thin film transistors are provided on the base substrate 211. Portions of the light-shielding layer 213 corresponding to different thin film transistors are spaced apart from each other, and portions of the light-shielding layer 213 corresponding to the first channel region 2124 and the second channel region 2125 of a same thin film transistor are a first sub light-shielding portions 213a and a second sub light-shielding portions 213b, respectively. The first sub light-shielding portion 213a and the second sub light-shielding portion 213b are spaced apart from each other. It can be seen from FIG. 6, the distance between a side of the second sub light-shielding portion 213b farthest away from the connection portion 2123 and the connection portion 2123 is greater than the distance between a side of the first sub light-shielding portion 213a farthest away from the connection portion 2123 and the connection portion 2123.

For example, as shown in FIG. 6, an end of the second branch portion 2122 away from the connection portion 2123 corresponds to the second via hole structure 2127, the second via hole structure 2127 is farther away from the connection portion 2123 relative to the first via hole structure 2126. That is, in the planar view shown in FIG. 6, both the first branch portion 2121 and the second branch portion 2122 are elongated, and extend in the first direction X. Moreover, the length of the second branch portion 2122 in the first direction X is greater than the length of the first branch portion 2121 in the first direction X, i.e., the distance between the second via hole structure 2127 and the connection portion 2123 is greater than the distance between the first via hole structure 2126 and the connection portion 2123 in the first direction X, such that the second via hole structure 2127 corresponding to the end of the second branch portion 2122 and the first via hole structure 2126 corresponding to the end of the first branch portion 2121 are not leveling.

For example, as shown in FIG. 6, the orthographic projections of the first channel region 2124 and the first via hole structure 2126 on the base substrate 211 is covered by the first sub-shielding portion 213a, and the orthographic projection of the second channel region 2125 on the base substrate 211, but not the orthographic projection of the second via hole structure 2127 on the base substrate 211, is covered by the second sub-shielding portion 213b. Occurrence of leakage current phenomenon can be reduced by the array substrate 21 by designing the first sub-shielding portion 213a to cover the orthographic projections of the first channel region 2124 and the first via hole structure 2126 on the base substrate 211, and designing the second sub-shielding portion 213b to cover the orthographic projection of the second channel region 2125 on the base substrate 211, so that the holding capability of the pixel capacitance is improved, thereby the problem of flicker at a low frequency can be alleviated, and the aperture ratio of the display panel formed later can also be ensured.

For example, as shown in FIG. 6, the orthographic projection of the first via hole structure 2126 on the base substrate 211 is located within the orthographic projection of the first sub light-shielding portion 213a on the base substrate 211, and the orthographic projection of the second via hole structure 2127 on the base substrate 211 is located outside the orthographic projection of the second sub light-shielding portion 213b on the base substrate 211.

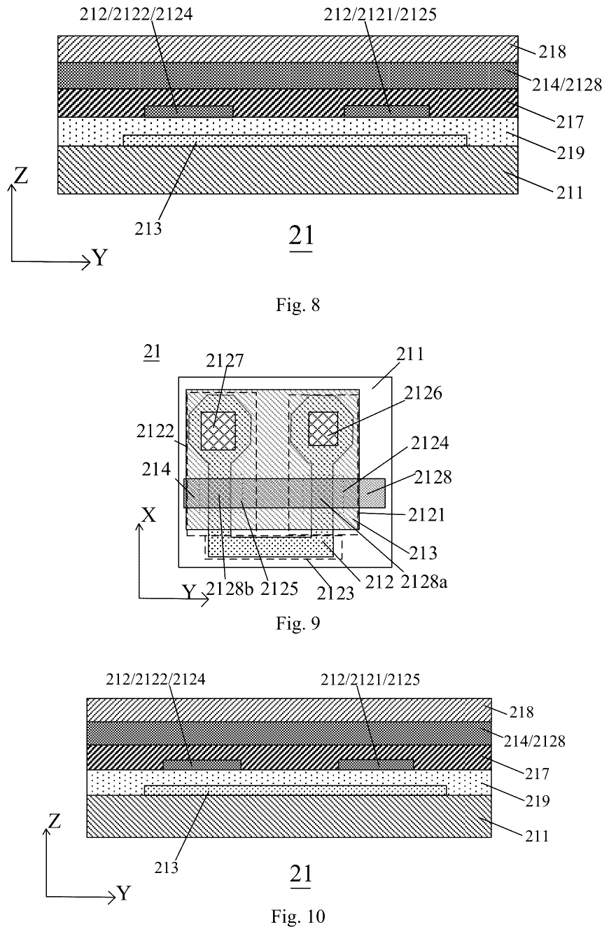

For example, FIG. 7 is a schematic diagram of a stacked structure of yet another array substrate provided by at least one embodiment of the present disclosure, and FIG. 8 is a schematic diagram of a cross-sectional structure of the array substrate in FIG. 7. For example, in combination with FIG. 7 and FIG. 8, the array substrate 21 comprises a base substrate 211, and a light-shielding layer 213 and a semiconductor layer 212 that are stacked on the base substrate 211. The semiconductor layer 212 comprises a first branch portion 2121 and a second branch portion 2122 that are provided opposite to each other, and a connection portion 2123 connecting the first branch portion 2121 and the second branch portion 2122. The first branch portion 2121 comprises a first channel region 2124, and the second branch portion 2122 comprises the second channel region 2125. An end of the first branch portion 2121 away from the connection portion 2123 corresponds to a first via hole structure 2126. That is, the first branch portion 2121 has the first via hole structure 2126 on a side of the first branch portion 2121 away from the base substrate 211. Moreover, the orthographic projection of the first via hole structure 2126 on the base substrate 211 is located within the orthographic projection of the end of the first branch portion 2121 away from the connection portion 2123 on the base substrate 211. An end of the second branch portion 2122 away from the connection portion 2123 corresponds to a second via hole structure 2127. That is, the second branch portion 2122 has the second via hole structure 2127 on a side of the second branch portion 2122 away from the base substrate 211. Moreover, the orthographic projection of the second via hole structure 2127 on the base substrate 211 is located within the orthographic projection of the end of the second branch portion 2122 away from the connection portion 2123 on the base substrate 211. The orthographic projections of the first channel region 2124, the second channel region 2125, the first via hole structure 2126, and the second via hole structure 2127 on the base substrate 211 are covered by the orthographic projection of the light-shielding layer 213 on the base substrate 211. Occurrence of leakage current phenomenon can be reduced by the array substrate 21 by making all regions of the first channel region 2124, the second channel region 2125, the first via hole structure 2126, and the second via hole structure 2127 be covered by the light-shielding layer 213, so that the holding capability of the pixel capacitance is improved, thereby the problem of flicker at a low frequency can be alleviated, and the aperture ratio of the display panel formed later can also be ensured.

For example, referring to FIG. 7, in the first direction X, the second via hole structure 2127 is farther away from the connection portion 2123 relative to the first via hole structure 2126. That is, in the planar view shown in FIG. 7, both the first branch portion 2121 and the second branch portion 2122 are elongated and extend in the first direction X. Moreover, the length of the second branch portion 2122 in the first direction X is greater than the length of the first branch portion 2121 in the first direction X, i.e., in the first direction X, the distance between the second via hole structure 2127 and the connection portion 2123 is greater than the distance between the first via hole structure 2126 and the connection portion 2123, so that the second via hole structure 2127 corresponding to the end of the second branch portion 2122 and the first via hole structure 2126 corresponding to the end of the first branch portion 2121 are not leveling.

For example, in combination with FIG. 7 and FIG. 8, the array substrate 21 further comprises a first metal layer 214 provided on a side of the semiconductor layer 212 away from the base substrate 211. The first metal layer 214 comprises a gate line 2128 extending in the second direction Y. The gate line 2128 is elongated, and comprises a first gate electrode 2128a and a second gate electrode 2128b. An orthographic projection of the first gate electrode 2128a on the base substrate 211 overlaps with the orthographic projection of the first channel region 2124 on the base substrate 211, and an orthographic projection of the second gate electrode 2128b on the base substrate 211 overlaps with the orthographic projection of the second channel region 2125 on the base substrate 211.

For example, the first gate electrode 2128a, the second gate electrode 2128b, and the gate line 2128 are in an integral linear structure. The first gate electrode 2128a and the second gate electrode 2128b are portions of the gate line 2128. The first gate electrode 2128a is a portion of the gate line 2128 corresponding to the first channel region 2124, and the second gate electrode 2128b is a portion of the gate line 2128 corresponding to the second channel region 2125.

For example, as shown in FIG. 8, a first insulating layer 219 is provided between the light-shielding layer 213 and the semiconductor layer 212; a gate insulating layer 217 is provided between the first insulating layer 219 and the first metal layer 214; and an interlayer insulating layer 218 is provided on a side of the first metal layer 214 away from the base substrate 211.

For example, as shown in FIG. 7 and FIG. 8, the orthographic projection of an edge of the light-shielding layer 213 away from the connection portion 2123 on the base substrate 211 comprises a first portion 213c located on a side of the first via hole structure 2124 away from the connection portion 2123, and a second portion 213d located on a side of the second via hole structure 2127 away from the connection portion 2123. The upper edge of the first portion 213c and the upper edge of the second portion 213d are not on the same straight line. That is, the planar shape of the light-shielding layer 213 is stepped. In the first direction X, the distance between the first portion 213c and the connection portion 2123 is greater than the distance between the second portion 213d and the connection portion 2123. The orthographic projection of the second via hole structure 2127 on the base substrate 211 is located within the orthographic projection of the light-shielding layer 213 on the base substrate 211. It should be noted that, in this embodiment, a material of the light-shielding layer 213 is a non-conductive light-shielding material. When the material of the light-shielding layer 213 is a non-conductive light-shielding material, the problem of short circuit between the first source/drain electrode and a second source/drain electrode of the thin film transistor will not occur, even if the phenomenon that the interlayer insulating layer 218 is over-etched to the light-shielding layer 213 occurs.

For example, FIG. 9 is a schematic diagram of a planar structure of yet another array substrate provided by at least one embodiment of the present disclosure, and FIG. 10 is a schematic diagram of a cross-sectional structure of the array substrate shown in FIG. 9. For example, in combination with FIG. 9 and FIG. 10, the array substrate 21 comprises a base substrate 211, and a light-shielding layer 213 and a semiconductor layer 212 that are stacked on the base substrate 211. The semiconductor layer 212 comprises a first branch portion 2121 and a second branch portion 2122 that are provided opposite to each other, and the connection portion 2123 connecting a first branch portion 2121 and a second branch portion 2122. The first branch portion 2121 comprises a first channel region 2124, and the second branch portion 2122 comprises a second channel region 2125. An end of the first branch portion 2121 away from the connection portion 2123 corresponds to a first via hole structure 2126. That is, the first branch portion 2121 has the first via hole structure 2126 on a side of the first branch portion 2121 away from the base substrate 211. Moreover, the orthographic projection of the first via hole structure 2126 on the base substrate 211 is located within the orthographic projection of an end of the first branch portion 2121 that is away from the connection portion 2123 on the base substrate 211. An end of the second branch portion 2122 away from the connection portion 2123 corresponds to a second via hole structure 2127. That is, the second branch portion 2122 has the second via hole structure 2127 on a side of the second branch portion 2122 away from the base substrate 211. Moreover, the orthographic projection of the second via hole structure 2127 on the base substrate 211 is located within the orthographic projection of the end of the second branch 2122 away from the connection portion 2123 on the base substrate 211. The orthographic projections of the first channel region 2124, the second channel region 2125, the first via hole structure 2126, and the second via hole structure 2127 on the base substrate 211 are covered by the orthographic projection of the light-shielding layer 213 on the base substrate 211. Occurrence of leakage current phenomenon can be reduced by the array substrate 21 by making all regions of the first channel region 2124, the second channel region 2125, the first via hole structure 2126, and the second via hole structure 2127 be covered by the light-shielding layer 213, so that the holding capability of the pixel capacitance is improved, thereby the problem of flicker at a low frequency can be alleviated, and the aperture ratio of the display panel formed later can also be ensured.

For example, referring to FIG. 9, an end of the second branch portion 2122 away from the connection portion 2123 corresponds to the second via hole structure 2127. In the first direction X, the distance between the second via hole structure 2127 and the connection portion 2123 is equal to the distance between the first via hole structure 2124 and the connection portion 2123. That is, in the planar view shown in FIG. 9, both the first branch portion 2121 and the second branch portion 2122 are elongated and extend in the first direction X. Moreover, the length of the second branch portion 2122 in the first direction X is equal to the length of the first branch portion 2121 in the first direction X, so that the second via hole structure 2127 corresponding to the end of the second branch portion 2122 and the first via hole structure 2124 corresponding to the end of the first branch portion 2121 are leveling.

For example, in combination with FIG. 9 and FIG. 10, the array substrate 21 further comprises a first metal layer 214 provided on a side of the semiconductor layer 212 away from the substrate 211. The first metal layer 214 comprises a gate line 2128 extending in the second direction Y. The gate line 2128 is elongated, and comprises a first gate electrode 2128a and a second gate electrode 2128b. The orthographic projection of the first gate electrode 2128a on the base substrate 211 overlaps with the orthographic projection of the first channel region 2124 on the base substrate 211, and the orthographic projection of the second gate electrode 2128b on the base substrate 211 overlaps with the orthographic projection of the second channel region 2125 on the base substrate 211. For example, the first gate electrode 2128a, the second gate electrode 2128b, and the gate line 2128 are in an integral linear structure. The first gate electrode 2128a and the second gate electrode 2128b are portions of the gate line 2128. The first gate electrode 2128a is a portion of the gate line 2128 corresponding to the first channel region 2124, and the second gate electrode 2128b is a portion of the gate line 2128 corresponding to the second channel region 2125.

For example, as shown in FIG. 10, a first insulating layer 219 is provided between the light-shielding layer 213 and the semiconductor layer 212; a gate insulating layer 217 is provided between the first insulating layer 219 and the first metal layer 214; and an interlayer insulating layer 218 is provided on a side of the first metal layer 214 away from the base substrate 211.

For example, in combination with FIG. 9 and FIG. 10, in one embodiment, a material of the light-shielding layer 213 comprises a non-conductive light shielding material. The orthographic projections of the first via hole structure 2126 and the second via hole structure 2127 on the base substrate 211 are both located within the orthographic projection of the light-shielding layer 213 on the base substrate 211.

For example, in combination with FIG. 9 and FIG. 10, the light-shielding layer 213 is in an integral structure. The orthographic projection of the first channel region 2124 on the base substrate 211, the orthographic projection of the second channel region 2125 on the base substrate 211, the orthographic projection of the first via hole structure 2126 on the base substrate 211, and the orthographic projection of the second via hole structure 2127 on the base substrate 211, and also the gap between the first channel region 2124 and the second channel region 2125, and also the gap between the first via hole structure 2126 and the second via hole structure 2127 are covered by the orthographic projection of the light-shielding layer 213 on the base substrate 211.

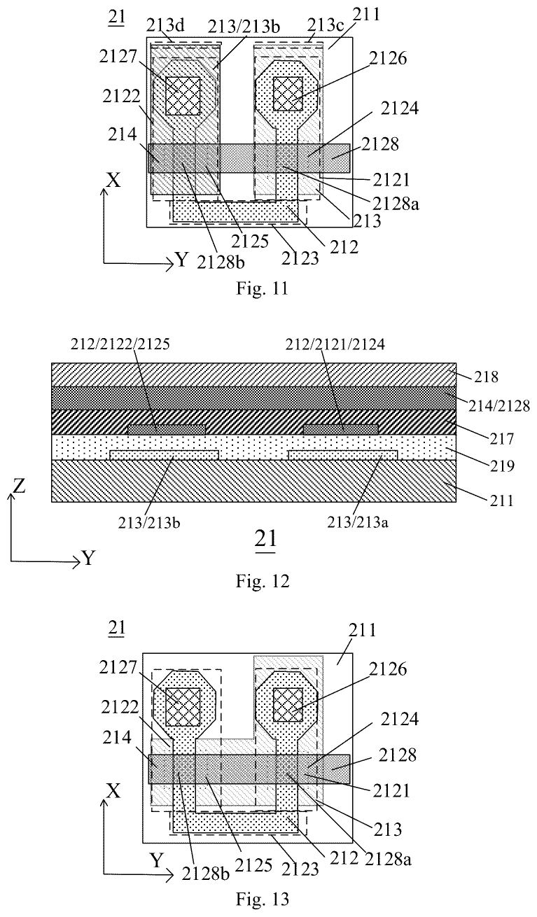

For example, FIG. 11 is a schematic diagram of a planar structure of yet another array substrate provided by at least one embodiment of the present disclosure, and FIG. 12 is a schematic diagram of a cross-sectional structure of the array substrate shown in FIG. 11. For example, in combination with FIG. 11 and FIG. 12, the array substrate 21 comprises a base substrate 211, and a light-shielding layer 213 and a semiconductor layer 212 that are stacked on the base substrate 211. The semiconductor layer 212 comprises a first branch portion 2121 and a second branch portion 2122 that are provided opposite to each other, and the connection portion 2123 connecting a first branch portion 2121 and a second branch portion 2122. The first branch portion 2121 comprises a first channel region 2124, and the second branch portion 2122 comprises a second channel region 2125. An end of the first branch portion 2121 away from the connection portion 2123 corresponds to a first via hole structure 2126. That is, the first branch portion 2121 has the first via hole structure 2126 on a side of the first branch portion 2121 away from the base substrate 211. Moreover, the orthographic projection of the first via hole structure 2126 on the base substrate 211 is located within the orthographic projection of an end of the first branch portion 2121 away from the connection portion 2123 on the base substrate 211. Portions of the light-shielding layer 213 corresponding to different thin film transistors are spaced apart from each other, and portions of the light-shielding layer 213 corresponding to the first channel region 2124 and the second channel region 2125 of the same thin film transistor are a first sub light-shielding portion 213a and a second sub light-shielding portion 213b, respectively. The first sub light-shielding portion 213a and the second sub light-shielding portion 213b are spaced apart from each other. The orthographic projections of the first channel region 2124 and the first via hole structure 2126 on the base substrate 211 is covered by the first sub-shielding portion 213a, and the orthographic projections of the second channel region 2125 and the second via hole structure 2127 on the base substrate 211 are covered by the second sub-shielding portion 213b. Occurrence of leakage current phenomenon can be reduced by the array substrate 21 by designing the first sub-shielding portion 213a as such that the orthographic projections of the first channel region 2124 and the first via hole structure 2126 on the base substrate 211 are covered by the orthographic projection of the first sub-shielding portion 213a on the base substrate 211, and designing the second sub-shielding portion 213b as such that the orthographic projections of the second channel region 2125 and the second via hole structure 2127 on the base substrate 211 are covered by the orthographic projection of the second sub-shielding portion 213b on the base substrate 211, so that the holding capability of pixel capacitance is improved, thereby the problem of flicker at a low frequency can be alleviated, and the aperture ratio of the display panel formed later can also be ensured.

For example, referring to FIG. 11, an end of the second branch portion 2122 away from the connection portion 2123 corresponds to the second via hole structure 2127, which is farther away from the connection portion 2123 relative to the first via hole structure 2126. That is, in the planar view shown in FIG. 11, both the first branch portion 2121 and the second branch portion 2122 are elongated, and extend in the first direction X. The length of the second branch portion 2122 in the first direction X is equal to that of the first branch portion 2121 in the first direction X, i.e., in the first direction X, the distance between the second via hole structure 2127 and the connection portion 2123 is equal to that between the first via hole structure 2126 and the connection portion 2123, such that the second via hole structure 2127 corresponding to the end of the second branch portion 2122 and the first via hole structure 2126 corresponding to the end of the first branch portion 2121 are leveling.

For example, in combination with FIG. 11 and FIG. 12, the array substrate 21 further comprises a first metal layer 214 provided on a side of the semiconductor layer 212 away from the substrate 211. The first metal layer 214 comprises a gate line 2128 extending in the second direction Y. The gate line 2128 is elongated, and comprises a first gate electrode 2128a and a second gate electrode 2128b. The orthographic projection of the first gate electrode 2128a on the base substrate 211 overlaps with the orthographic projection of the first channel region 2124 on the base substrate 211, and the orthographic projection of the second gate electrode 2128b on the base substrate 211 overlaps with the orthographic projection of the second channel region 2125 on the base substrate 211.

For example, the first gate electrode 2128a, the second gate electrode 2128b, and the gate line 2128 are in an integral linear structure. The first gate electrode 2128a and the second gate electrode 2128b are portions of the gate line 2128. The first gate electrode 2128a is a portion of the gate line 2128 corresponding to the first channel region 2124, and the second gate electrode 2128b is a portion of the gate line 2128 corresponding to the second channel region 2125.

For example, as shown in FIG. 12, a first insulating layer 219 is provided between the light-shielding layer 213 and the semiconductor layer 212; a gate insulating layer 217 is provided between the first insulating layer 219 and the first metal layer 214; and an interlayer insulating layer 218 is provided on a side of the first metal layer 214 away from the base substrate 211.

For example, as shown in FIG. 11 and FIG. 12, the orthographic projection of an edge of the first sub-shielding portion 213a away from the connection portion 2123 on the base substrate 211 comprises a first portion 213c located on a side of the first via hole structure 2126 away from the connection portion 2123, and the orthographic projection of an edge of the second sub-shielding portion 213b away from the connection portion 2123 on the base substrate 211 comprises a second portion 213d located on a side of the second via hole structure 2127 away from the connection portion 2123. That is, the planar shapes of the first sub-shielding portion 213a and the second sub-shielding portion 213b are both elongated, and the length of the first sub-shielding portion 213a is equal to the length of the second sub-shielding portion 213b. In the first direction X, the distance between the first portion 213c and the connection portion 2123 is equal to the distance between the second portion 213d and the connection portion 2123. The orthographic projection of the second via hole structure 2127 on the base substrate 211 is located within the orthographic projection of the light-shielding layer 213 on the base substrate 211. It should be noted that, in this embodiment, material of the light-shielding layer 213 is a non-conductive light-shielding material. The problem of short circuit between the first source/drain electrode and the second source/drain electrode of the thin film transistor will not occur, even if the phenomenon that the interlayer insulating layer 218 is over-etched to the light-shielding layer 213 occurs.

For example, a plurality of thin film transistors are provided on the array substrate 21. Portions of the light-shielding layer 213 corresponding to different thin film transistors are spaced apart from each other. In combination with FIG. 11 and FIG. 12, portions of the light-shielding layer 213 corresponding to the first channel region 2124 and the second channel region 2125 of the same thin film transistor are a first sub light-shielding portion 213a and a second sub light-shielding portion 213b, respectively. The first sub light-shielding portion 213a and the second sub light-shielding portion 213b are spaced apart from each other. The orthographic projection of the first channel region 2124 on the base substrate 211 is completely located within the orthographic projection of the first sub light-shielding portion 213a on the base substrate 211, and the orthographic projection of the second channel region 2125 on the base substrate 211 is completely located within the orthographic projection of the second sub light-shielding portion 213b on the base substrate 211. The orthographic projection of the first via hole structure 2126 on the base substrate 211 is located within the orthographic projection of the first sub light-shielding portion 213a on the base substrate 211, and the orthographic projection of the second via hole structure 2127 on the base substrate 211 is located within the orthographic projection of the second sub light-shielding portion 213b on the base substrate 211.

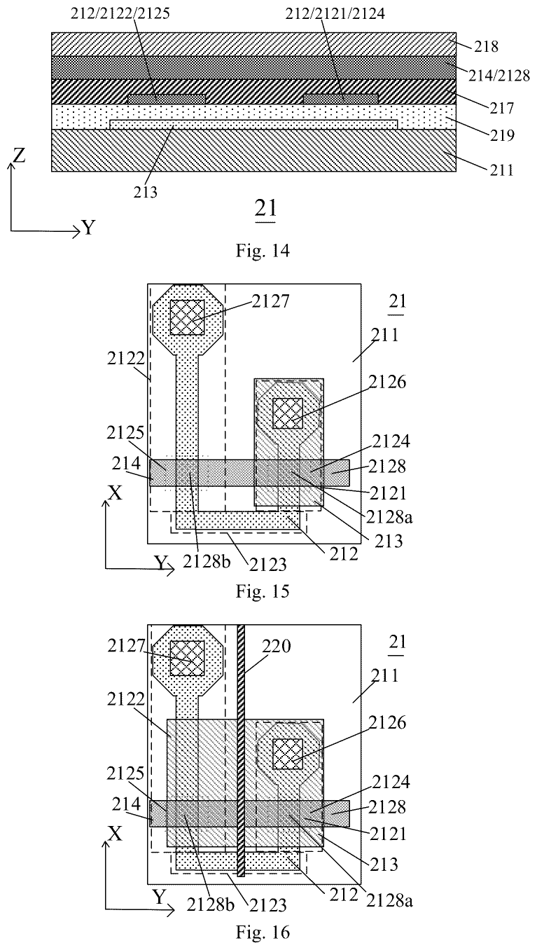

For example, FIG. 13 is a schematic diagram of a planar structure of yet another array substrate provided by at least one embodiment of the present disclosure, and FIG. 14 is a schematic diagram of a cross-sectional structure of the array substrate shown in FIG. 13. As shown in FIG. 13, the array substrate 21 comprises a base substrate 211, and a light-shielding layer 213 and a semiconductor layer 212 that are stacked on the base substrate 211. The semiconductor layer 212 comprises a first branch portion 2121 and a second branch portion 2122 that are provided opposite to each other, and a connection portion 2123 connecting the first branch portion 2121 and the second branch portion 2122. The first branch portion 2121 comprises a first channel region 2124, and the second branch portion 2122 comprises a second channel region 2125. An end of the first branch portion 2121 away from the connection portion 2123 corresponds to a first via hole structure 2126. That is, the first branch portion 2121 has the first via hole structure 2126 on a side of the first branch portion 2121 away from the base substrate 211. The orthographic projection of the first via hole structure 2126 on the base substrate 211 is located within the orthographic projection of the end of the first branch portion 2121 away from the connection portion 2123 on the base substrate 211. An end of the second branch portion 2122 away from the connection portion 2123 corresponds to the second via hole structure 2127. That is, the second branch portion 2122 has a second via hole structure 2127 on a side of the second branch portion 2122 away from the base substrate 211. The orthographic projection of the second via hole structure 2127 on the base substrate 211 is located within the orthographic projection of the end of the second branch portion 2122 away the connection portion 2123 on the base substrate 211. The orthographic projections of the first channel region 2124, the second channel region 2125, and the first via hole structure 2126 on the base substrate 311 are covered by the orthographic projection of the light-shielding layer 213 on the base substrate 211. Occurrence of leakage current phenomenon can be reduced by the array substrate 21 via making all regions of the first channel region 2124, the second channel region 2125, and the first via hole structure 2126 be covered by the light-shielding layer 213, so that the holding capability of pixel capacitance is improved, thereby the problem of flicker at a low frequency can be alleviated, and the aperture ratio of the display panel formed later can also be ensured.

For example, as shown in FIG. 13, in the first direction X, the distance between the second via hole structure 2127 and the connection portion 2123 is equal to the distance between the first via hole structure 2124 and the connection portion 2123. That is, in the planar view shown in FIG. 13, both the first branch portion 2121 and the second branch portion 2122 are elongated, and extend in the first direction X. Moreover, the length of the second branch portion 2122 in the first direction X is equal to that of the first branch portion 2121 in the first direction X, such that the second via hole structure 2127 corresponding to the end of the second branch portion 2122 and the first via hole structure 2124 corresponding to the end of the first branch portion 2121 are leveling.

For example, as shown in FIG. 13, the array substrate 21 further comprises a first metal layer 214 provided on a side of the semiconductor layer 212 away from the substrate 211. The first metal layer 214 comprises a gate line 2128 extending in the second direction Y. The gate line 2128 is elongated, and comprises a first gate electrode 2128a and a second gate electrode 2128b. The orthographic projection of the first gate electrode 2128a on the base substrate 211 overlaps with the orthographic projection of the first channel region 2124 on the base substrate 211, and the orthographic projection of the second gate electrode 2128b on the base substrate 211 overlaps with the orthographic projection of the second channel region 2125 on the base substrate 211.

For example, the first gate electrode 2128a, the second gate electrode 2128b, and the gate line 2128 are in an integral linear structure. The first gate electrode 2128a and the second gate electrode 2128b are portions of the gate line 2128. The first gate electrode 2128a is a portion of the gate line 2128 corresponding to the first channel region 2124, and the second gate electrode 2128b is a portion of the gate line 2128 corresponding to the second channel region 2125.

For example, as shown in FIG. 14, a first insulating layer 219 is provided between the light-shielding layer 213 and the semiconductor layer 212; a gate insulating layer 217 is provided between the first insulating layer 219 and the first metal layer 214; and an interlayer insulating layer 218 is provided on a side of the first metal layer 214 away from the base substrate 211.

For example, in combination with FIG. 13 and FIG. 14, in one embodiment, a material of the light-shielding layer 213 comprises a non-conductive light shielding material or a conductive light shielding material. The orthographic projection of the first via hole structure 2126 on the base substrate 211 is located within the orthographic projection of the light-shielding layer 213 on the base substrate 211.

For example, in combination with FIG. 13 and FIG. 14, the light-shielding layer 213 is in an integral structure. The orthographic projection of the first channel region 2124 on the base substrate 211, the orthographic projection of the second channel region 2125 on the base substrate 211, the orthographic projection of the first via hole structure 2126 on the base substrate 211, and also the gap between the first channel region 2124 and the second channel region 2125 are covered by the orthographic projection of the light-shielding layer 213 on the base substrate 211. The light-shielding layer 213 has a stepped planar shape.

For example, FIG. 15 is a schematic diagram of a stacked structure of yet another array substrate provided by at least one embodiment of the present disclosure. In one embodiment, a plurality of thin film transistors are provided on the substrate 211. Portions of the light-shielding layer 213 corresponding to different thin film transistors are spaced apart from each other. The light-shielding layer 213 only corresponds to the first channel region 2124 of the same thin film transistor. That is, the orthographic projection of the light-shielding layer 213 on the base substrate 211 only covers the orthographic projection of the first channel region 2124 on the base substrate 211, and does not cover the orthographic projection of the second channel region 2125 on the base substrate 211.

For example, as shown in FIG. 15, an end of the second branch portion 2122 away from the connection portion 2123 corresponds to a second via hole structure 2127, which is farther away from the connection portion 2123 relative to the first via hole structure 2126. That is, in the planar view shown in FIG. 15, both the first branch portion 2121 and the second branch portion 2122 are elongated, and extend in the first direction X. Moreover, the length of the second branch portion 2122 in the first direction X is larger than that of the first branch portion 2121 in the first direction X, i.e., in the first direction X, the distance between the second via hole structure 2127 and the connection portion 2123 is greater than that between the first via hole structure 2126 and the connection portion 2123, such that the second via hole structure 2127 corresponding to the end of the second branch portion 2122 and the first via hole structure 2124 corresponding to the end of the first branch portion 2121 are not leveling.

For example, as shown in FIG. 15, occurrence of leakage current phenomenon can be reduced by the array substrate 21 via designing the light-shielding layer 213 to cover the orthographic projections of the first channel region 2124 and the first via hole structure 2126 on the base substrate 211, so that holding capability of pixel capacitance is improved, thereby the problem of flicker at a low frequency can be alleviated, and the aperture ratio of the display panel formed later can also be ensured.

For example, FIG. 16 is a schematic diagram of a stacked structure of yet another array substrate provided by at least one embodiment of the present disclosure. The array substrate shown in FIG. 16 is different from the array substrate shown in FIG. 5 only in that a touch signal line 220 extending along the first direction X is provided between the first branch portions 2121 and the second branch portions 2122. Such a design can save space for placing traces, so that the array substrate is thinner and lighter. The structure of the array substrate shown in FIG. 16 may refer to the related description of the array substrate shown in FIG. 5, and is not repeated herein.

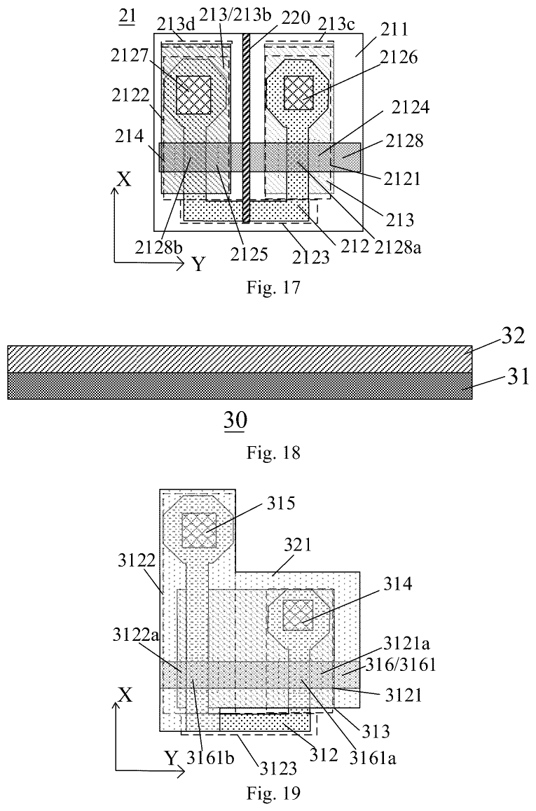

For example, FIG. 17 is a schematic diagram of a stacked structure of yet another array substrate provided by at least one embodiment of the present disclosure. The array substrate shown in FIG. 17 is different from the array substrate shown in FIG. 11 only in that a touch signal line 220 extending along the first direction X is provided between the first branch portions 2121 and the second branch portions 2122. Such a design can save space for placing traces, so that the array substrate is thinner and lighter. The structure of the array substrate shown in FIG. 17 may refer to the related description of the array substrate shown in FIG. 11, and is not repeated herein.

For example, for the display panel, a black matrix may be further provided on an opposing substrate provided opposite to the array substrate, and the length of the space region shielded below the gate line in the first direction X by the light-shielding layer may be reduced, so that edges of the light-shielding layer are all contracted into regions covered by the black matrix, thereby the aperture ratio of the display panel may be further improved.

At least one embodiment of the present disclosure provides a display panel, the display panel includes a first substrate and a second substrate that are disposed opposite to each other, in which the first substrate comprises a base substrate, and a semiconductor layer and a light-shielding layer that are stacked on the base substrate; the second substrate comprises a black matrix; the semiconductor layer comprises a first branch portion and a second branch portion that are provided opposite to each other, and a connection portion connecting the first branch portion and the second branch portion, the first branch portion comprises a first channel region, and the second branch portion comprises a second channel region; the first branch portion has a first via hole structure on a side of the first branch portion away from the base substrate, and the orthographic projection of the first via hole structure on the base substrate is located within the orthographic projection of an end of the first branch portion away from the connection portion on the base substrate; the orthographic projection of the light-shielding layer on the base substrate is located within the orthographic projection of the black matrix on the base substrate, and covers at least the orthographic projections of the first channel region and the first via hole structure on the base substrate. Leakage current of a display panel formed later can be reduced by the display panel via adjusting design of the light-shielding layer, so that the holding capability of pixel capacitance is improved, thereby the problem of flicker at a low frequency can be alleviated, and aperture ratio of the display panel formed later can also be ensured. Further, edges of the light-shielding layer are contracted into regions covered by the black matrix, so that the aperture ratio of the display panel can be further improved.

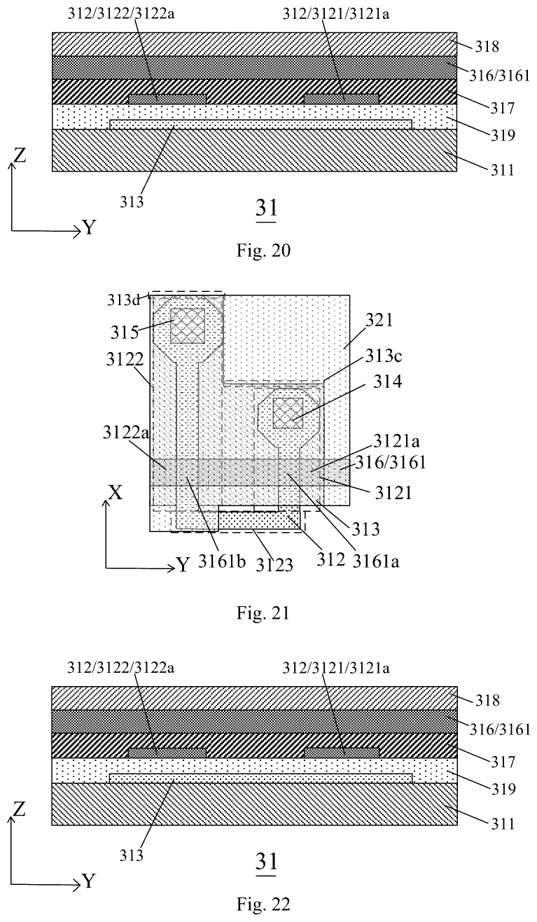

For example, FIG. 18 is a schematic diagram of a cross-sectional structure of a display panel provided by at least one embodiment of the present disclosure, FIG. 19 is a schematic diagram of a planar structure of a display panel provided by at least one embodiment of the present disclosure, and FIG. 20 is a schematic diagram of a cross-sectional structure of a first substrate provided by at least one embodiment of the present disclosure. In combination with FIG. 18, FIG. 19, and FIG. 20, the display panel 30 comprises a first substrate 31 and a second substrate 32 that are provided opposite to each other. The first substrate 31 comprises a base substrate 311, and a light-shielding layer 313 and a semiconductor layer 312 that are stacked on the base substrate 311. The second substrate 32 comprises a black matrix 321. The semiconductor layer 312 comprises a first branch portion 3121 and a second branch portion 3122 that are provided opposite to each other, and a connection portion 3123 connecting the first branch portion 3121 and the second branch portion 3122. The first branch portion 3121 comprises a first channel region 3121a, and the second branch portion 3122 comprises a second channel region 3122a. An end of the first branch portion 3121 away from the connection portion 3123 corresponds to a first via hole structure 314. That is, the first branch portion 3121 has the first via hole structure 314 on a side of the first branch portion 3121 away from the base substrate 311. Moreover, the orthographic projection of the first via hole structure 314 on the base substrate 311 is located within the orthographic projection of an end of the first branch portion 3121 away from the connection portion 3123 on the base substrate 311. The orthographic projection of the light-shielding layer 313 on the base substrate 311 is located within the orthographic projection of the black matrix 321 on the base substrate 311, and covers at least the orthographic projections of the first channel region 3121a, the second channel region 3122a and the first via hole structure 314 on the base substrate 311. Occurrence of leakage current phenomenon in a display panel formed later can be reduced by the display panel 30 by designing the black matrix 321 as such that all regions of the light-shielding layer 313 is covered by it, and designing the light-shielding layer 313 as such that all regions of the first channel region 3121a, the second channel region 3122a and the first via hole structure 314 are covered by it, so that holding capability of pixel capacitance is improved, thereby the problem of flicker at a low frequency can be alleviated, and aperture ratio of the display panel formed later can also be ensured.

It should be noted that the semiconductor layer is a state in the process of manufacturing the display panel, and there are other subsequent processes to make part of the semiconductor region conductive. That is, after the gate electrode and gate line mentioned later are formed, there is also a heavily-doping step to turn the portion of the semiconductor layer outside the region covered by the gate electrode into a conductor, so that the channel region can be shielded by the gate electrode. Thus, the semiconductor layer located below the gate electrode corresponds to the channel region.

It should also be noted that, although in the embodiment shown in FIG. 19, the second channel region 3122a is covered by the light-shielding layer 313, in other embodiments, the second channel region 3122a may also not be covered by the light-shielding layer 313.

For example, in one embodiment, the first substrate 31 is an array substrate, and the second substrate 32 is an opposing substrate provided opposite to the array substrate, such as a color-film base substrate. Other structures on the color filter substrate may refer to conventional designs and are not described herein.

For example, referring to FIG. 19, an end of the second branch portion 3122 away from the connection portion 3123 corresponds to the second via hole structure 315, which is farther away from the connection portion 3123 relative to the first via hole structure 314. That is, in the planar view shown in FIG. 19, both the first branch portion 3121 and the second branch portion 3122 are elongated, and extend in the first direction X. Moreover, the length of the second branch portion 3122 in the first direction X is greater than that of the first branch portion 3121 in the first direction X, i.e., in the first direction X, the minimum distance between the second via hole structure 315 and the connection portion 3123 is greater than that between the first via hole structure 314 and the connection portion 3123, such that the second via hole structure 315 corresponding to the end of the second branch portion 3122 and the first via hole structure 314 corresponding to the end of the first branch portion 3121 are not leveling.

For example, in combination with FIG. 19 and FIG. 20, the first substrate 31 further comprises a first metal layer 316 provided on a side of the semiconductor layer 312 away from the base substrate 311. The first metal layer 316 comprises a gate line 3161 extending in the second direction Y. The gate line 3161 is elongated and comprises a first gate electrode 3161a and a second gate electrode 3161b. The orthographic projection of the first gate electrode 3161a on the base substrate 311 overlaps with the orthographic projection of the first channel region 3121a on the base substrate 311, and the orthographic projection of the second gate electrode 3161b on the base substrate 311 overlaps with the orthographic projection of the second channel region 3122a on the base substrate 311.

For example, in combination with FIG. 19 and FIG. 20, the orthographic projection of the first gate electrode 3161a on the base substrate 311 is within the orthographic projection of the black matrix 321 on the base substrate 311, and the orthographic projection of the second gate electrode 3161b on the base substrate 311 is within the orthographic projection of the black matrix 321 on the base substrate 311, such that the first gate electrode 3161a and the second gate electrode 3161b are completely covered by the black matrix 321. Moreover, the entirety of the gate line 3161 is covered by the black matrix 321.

It should be noted that, in the embodiment shown in FIG. 19, a portion at the lower left corner of the connection portion 3123 (i.e., a portion of the connection portion 3123 corresponding to a side of the second branch portion 3122) is covered by the black matrix 321, such that there are two convex portions in the left portion of the black matrix. Moreover, although data line is not shown in FIG. 19, the data line is also covered by the black matrix 321 in an actual product. When a touch signal line is further provided on the display panel, the touch signal line is also covered by the black matrix.

For example, as shown in FIG. 20, a first insulating layer 319 is provided between the light-shielding layer 313 and the semiconductor layer 312; a gate insulating layer 317 is provided between the first insulating layer 319 and the first metal layer 316; and an interlayer insulating layer 318 is provided on a side of the first metal layer 316 away from the base substrate 311.

For example, in combination with FIG. 19 and FIG. 20, in an embodiment, a material of the light-shielding layer 313 comprises a conductive metal with light shielding properties. The orthographic projection of the first via hole structure 314 on the base substrate 311 is covered by both the orthographic projection of the black matrix 321 on the base substrate 311 and the orthographic projection of the light-shielding layer 313 on the base substrate 311, and the orthographic projection of the second via hole structure 315 on the base substrate 311 is located outside the orthographic projection of the light-shielding layer 313 on the base substrate 311.

It should be noted that, if the light-shielding layer 313 is used to shield the second via hole structure 315, the light-shielding layer 313 needs to be shielded by the black matrix 321. Considering that existence of alignment fluctuation in the process, when the light-shielding layer 313 is added here, alignment fluctuation pairs of the multilayer structure will lead to the need to design a wider black matrix, thereby causing the aperture ratio of pixels of the display panel formed later to be sacrificed. Based on the consideration for the yield of the display panel, there is a risk of over-etching to the light-shielding layer 313 when etching the interlayer insulating layer 318. Moreover, when material of the light-shielding layer 313 is a conductive metal with light-shielding properties, over-etching the interlayer insulating layer 318 may cause the problem of short circuit between the first source/drain electrode and the second source/drain electrode of the thin film transistor, thereby causing the thin film transistor to lose its switching function.

It should also be noted that, when material of the light-shielding layer 313 is not a conductive material with light-shielding properties, that is, when the material of the light-shielding layer 313 is an insulating material with light-shielding properties, the second via hole structure 315 may also be covered by the light-shielding layer 313. In this way, the problem of short circuit between the first source/drain electrode and the second source/drain electrode of the thin film transistor will not occur, even if the phenomenon that the interlayer insulating layer 318 is over-etched to the light-shielding layer 313 occurs.

For example, in an embodiment of the present disclosure, in combination with FIG. 19 and FIG. 20, the effect of being covered by the light-shielding layer 313 for the first via hole structure 314 on reducing the leakage current I_{off} of the thin film transistor is significant. When the region where the first channel region 3121a is shielded by the light-shielding layer 313 changes, the corresponding data of the leakage current I_{off} of the thin film transistor of the display panel is as follows: based on a conventional design (100%), it can be concluded from the ratio of the data obtained from the experimental item to the data obtained from the conventional design that, when the region where the first channel region 3121a is shielded by the light-shielding layer 313 is increased, improvement effect on the leakage current I_{off} of the thin film transistor of the display panel is significant, but adjustment of the area where the second channel region 3122a is shielded by the light-shielding layer 313 has a small influence on the characteristics of the thin film transistor. Thus, under the premix that the aperture ratio of the display panel to be formed later is not affected, influence on aperture ratio of the display panel to be formed later can be reduced by increasing the area where the first channel region 3121a is shielded by the light-shielding layer 313 as much as possible, making the first via hole structure 314 be shielded by the light-shielding layer 313, and reducing the area where the second channel region 3122a is shielded by the light-shielding layer 313.

For example, in an embodiment of the present disclosure, in order to ensure that no light leaks out from the first via hole structure 314, the first via hole structure 314 needs to be completely shielded by the black matrix 321, and in the first direction X, the distance between the first via hole structure 314 and an edge of the black matrix 321 that is adjacent to the first via hole structure 314 is 1.15 microns. Thus, in order to ensure that the aperture ratio of the display panel to be formed later is not affected by the light-shielding layer 313, in the first direction X, an upper edge of the light-shielding layer 313 corresponding to the right-side portion of the first via hole structure and an upper edge of the first via hole structure 314 are leveling.

For example, as shown in FIG. 19, in the first direction X, the distance from the upper edge of the first via hole structure 314 to the gate line 3161 is 6.15 microns; the first via hole structure 314 is completely shielded by the light-shielding layer 313; and the upper edge of the light-shielding layer 313 and the upper edge of the first via hole structure 314 are leveling. On the upper side of the gate line 3161, the first branch portion 3121 is shielded by the light-shielding layer 313 by a length of 6.15 microns. In the first direction X, at the lower side of the gate line 3161, the length of a portion of the black matrix 321 corresponding to a side of the first branch portion 3121 is 1.4 microns. In order to make the aperture ratio of the display panel to be formed later be not affected, in the first direction X, a lower edge of the light-shielding layer 313 corresponding to a side of the first branch portion 3121 is designed to be leveling with a lower edge of the portion of the black matrix 321 corresponding to a side of the first branch portion 3121, and the distance from the lower edge of the portion of the light-shielding layer 313 corresponding to a side of the first branch portion 3121 to the gate line 3161 is 1.4 microns. In the second direction Y, the length of the light-shielding layer 313 is long, the minimum distance between the right edge of the light-shielding layer 313 and the right edge of the first branch portion 3121 is 2.0 microns, and the minimum distance between the left edge of the light-shielding layer 313 and the left edge of the second branch portion 3122 is 2.0 microns. In addition, the light-shielding layer 313 is designed as a whole. The gap portion between the first branch portion 3121 and the second branch portion 3122 is completely shielded by the light-shielding layer 313. That is, sufficient shielding of the light-shielding layer 313 to the portions above the gate line 3161 is achieved. For example, when a display panel is designed based on the above numerical values, the transmittance of a light is 34% under an illumination of 6500 nit; and the transmittance of a light is 31% under an illumination of 20000 nit.

For example, when a display panel is designed based on the numerical values in the embodiments shown in FIG. 19 and FIG. 20 described above, 10 sets of experimental data on low-frequency flicker are obtained, which are −35.82, −33.53, −36.55, −36.45, −35.78, −38.12, −36.21, −36.45, −35.72, and −37.41, respectively. Thus, an average numerical value of flicker can be obtained as −36.204. Correspondingly, when a display panel is designed based on the numerical values of the conventional design in FIGS. 1, 10 sets of experimental data on low-frequency flicker are obtained, which are −28.12, −26.58, −26.09, −28.22, 27.35, −29.2, −27.63, −28.54, −27.86, and −29.51, respectively. Thus, an average numerical value of flicker can be obtained as −27.91. It can be concluded from the above experimental data that by optimizing the design of the light-shielding layer 313, the flicker degree of the display screen of the display panel can be effectively improved to meet the control standards of the display panel.

For example, in another embodiment, in the first direction X, the distance from an upper edge of the first via hole structure 314 to the gate line 3161 is 5.5 microns. The first via hole structure 314 is shielded by the light-shielding layer 313. An upper edge of the light-shielding layer 313 and an upper edge of the first via hole structure 314 are leveling. At an upper side of the gate line 3161, the first branch portion 3121 is shielded by the light-shielding layer 313 by a length of 5.5 microns. In the first direction X, at the lower side of the gate line 3161, the length of a portion of the black matrix 321 corresponding to a side of the first branch portion 3121 is 1.4 microns. In order to make the aperture ratio of the display panel to be formed later be not affected, in the first direction X, a lower edge of a portion of the light-shielding layer 313 corresponding to a side of the first branch portion 3121 is designed to be leveling with a lower edge of a portion of the black matrix 321 corresponding to a side of the first branch portion 3121, and the distance from the lower edge of the portion of the light-shielding layer 313 corresponding to the side of the first branch portion 3121 to the gate line 3161 is 1.4 microns. In the second direction Y, the length of the light-shielding layer 313 is long, the minimum distance between the right edge of the light-shielding layer 313 and the right edge of the first branch portion 3121 is 2.0 microns, and the minimum distance between the left edge of the light-shielding layer 313 and the left edge of the second branch portion 3122 is 2.0 microns. In addition, the light-shielding layer 313 is designed as a whole. The gap portion between the first branch portion 3121 and the second branch portion 3122 is completely shielded by the light-shielding layer 313. That is, sufficient shielding of the light-shielding layer 313 to the gap portions above the gate line 3161 is achieved. For example, when a display panel is designed based on the above numerical values, the transmittance of a light is 49% under an illumination of 6500 nit; and the transmittance of a light is 41% under an illumination of 20000 nit.

For example, in another embodiment, in the first direction X, the distance from an upper edge of the first via hole structure 314 to the gate line 3161 is 5 microns. The first via hole structure 314 is shielded by the light-shielding layer 313. An upper edge of the light-shielding layer 313 and an upper edge of the first via hole structure 314 are leveling. At an upper side of the gate line 3161, the first branch portion 3121 is shielded by the light-shielding layer 313 by a length of 5 microns. In the first direction X, at the lower side of the gate line 3161, the length of a portion of the black matrix 321 corresponding to a side of the first branch portion 3121 is 1.4 microns. In order to make the aperture ratio of the display panel to be formed later be not affected, in the first direction X, a lower edge of a portion of the light-shielding layer 313 corresponding to a side of the first branch portion 3121 is designed to be leveling with a lower edge of a portion of the black matrix 321 corresponding to a side of the first branch portion 3121, and the distance from the lower edge of the light-shielding layer 313 to the gate line 3161 is 1.4 microns. In the second direction Y, the length of the light-shielding layer 313 is long, the minimum distance between the right edge of the light-shielding layer 313 and the right edge of the first branch portion 3121 is 2.0 microns, and the minimum distance between the left edge of the light-shielding layer 313 and the left edge of the second branch portion 3122 is 2.0 microns. In addition, the light-shielding layer 313 is designed as a whole. The gap portion between the first branch portion 3121 and the second branch portion 3122 is completely shielded by the light-shielding layer 313. That is, sufficient shielding of the light-shielding layer 313 to the gap portions above the gate line 3161 is achieved. For example, when a display panel is designed based on the above numerical values, the transmittance of a light is 57% under an illumination of 6500 nit; and the transmittance of a light is 48% under an illumination of 20000 nit.

For example, in another embodiment, in the first direction X, the distance from the upper edge of the first via hole structure 314 to the gate line 3161 is 4.5 microns. The first via hole structure 314 is shielded by the light-shielding layer 313. An upper edge of the light-shielding layer 313 and an upper edge of the first via hole structure 314 are leveling. At an upper side of the gate line 3161, the first branch portion 3121 is shielded by the light-shielding layer 313 by a length of 5.5 microns. In the first direction X, at the lower side of the gate line 3161, the length of a portion of the black matrix 321 corresponding to a side of the first branch portion 3121 is 1.4 microns. In order to make the aperture ratio of the display panel to be formed later be not affected, in the first direction X, a lower edge of a portion of the light-shielding layer 313 corresponding to a side of the first branch portion 3121 is designed to be leveling with a lower edge of the black matrix 321, and the distance from the lower edge of the portion of the light-shielding layer 313 corresponding to the side of the first branch portion 3121 to the gate line 3161 is 1.4 microns. In the second direction Y, the length of the light-shielding layer 313 is long, the minimum distance between the right edge of the light-shielding layer 313 and the right edge of the first branch portion 3121 is 2.0 microns, and the minimum distance between the left edge of the light-shielding layer 313 and the left edge of the second branch portion 3122 is 2.0 microns. In addition, the light-shielding layer 313 is designed as a whole. The gap portion between the first branch portion 3121 and the second branch portion 3122 is completely shielded by the light-shielding layer 313. That is, sufficient shielding of the light-shielding layer 313 to the gap portions above the gate line 3161 is achieved. For example, when a display panel is designed based on the above numerical values, the transmittance of a light is 64% under an illumination of 6500 nit; and the transmittance of a light is 61% under an illumination of 20000 nit.

For example, in another embodiment, in the first direction X, the distance from the upper edge of the first via hole structure 314 to the gate line 3161 is 6.15 microns. The first via hole structure 314 is shielded by the light-shielding layer 313. An upper edge of the light-shielding layer 313 and an upper edge of the first via hole structure 314 are leveling. At an upper side of the gate line 3161, the first branch portion 3121 is shielded by the light-shielding layer 313 by a length of 6.15 microns. In the first direction X, at the lower side of the gate line 3161, the length of a portion of the black matrix 321 corresponding to a side of the first branch portion 3121 is 0.7 microns. In order to make the aperture ratio of the display panel to be formed later be not affected, in the first direction X, a lower edge of a portion of the light-shielding layer 313 corresponding to a side of the first branch portion 3121 is designed to be leveling with a lower edge of a portion of the black matrix 321 corresponding to a side of the first branch portion 3121, and the distance from the lower edge of the portion of the light-shielding layer 313 corresponding to the side of the first branch portion 3121 to the gate line 3161 is 0.7 microns. In the second direction Y, the length of the light-shielding layer 313 is long, the minimum distance between the right edge of the light-shielding layer 313 and the right edge of the first branch portion 3121 is 2.0 microns, and the minimum distance between the left edge of the light-shielding layer 313 and the left edge of the second branch portion 3122 is 2.0 microns. In addition, the light-shielding layer 313 is designed as a whole. The gap portion between the first branch portion 3121 and the second branch portion 3122 is completely shielded by the light-shielding layer 313. That is, sufficient shielding of the light-shielding layer 313 to the portions above the gate line 3161 is achieved. For example, when a display panel is designed based on the above numerical values, the transmittance of a light is 36% under an illumination of 6500 nit; and the transmittance of a light is 35% under an illumination of 20000 nit.

For example, in another embodiment, in the first direction X, the distance from the upper edge of the first via hole structure 314 to the gate line 3161 is 6.15 microns. The first via hole structure 314 is shielded by the light-shielding layer 313. An upper edge of the light-shielding layer 313 and an upper edge of the first via hole structure 314 are leveling. At an upper side of the gate line 3161, the first branch portion 3121 is shielded by the light-shielding layer 313 by a length of 6.15 microns. In the first direction X, at the lower side of the gate line 3161, the length of a portion of the black matrix 321 corresponding to a side of the first branch portion 3121 is 0 microns. In order to make the aperture ratio of the display panel to be formed later be not affected, in the first direction X, a lower edge of a portion of the light-shielding layer 313 corresponding to a side of the first branch portion 3121 is designed to be leveling with a lower edge of a portion of the black matrix 321 corresponding to a side of the first branch portion 3121, and the distance from the lower edge of the portion of the light-shielding layer 313 corresponding to the side of the first branch portion 3121 to the gate line 3161 is 0 microns. In the second direction Y, the length of the light-shielding layer 313 is long, the minimum distance between the right edge of the light-shielding layer 313 and the right edge of the first branch portion 3121 is 2.0 microns, and the minimum distance between the left edge of the light-shielding layer 313 and the left edge of the second branch portion 3122 is 2.0 microns. In addition, the light-shielding layer 313 is designed as a whole. The gap portion between the first branch portion 3121 and the second branch portion 3122 is completely shielded by the light-shielding layer 313. That is, sufficient shielding of the light-shielding layer 313 to the portions above the gate line 3161 is achieved. For example, when a display panel is designed based on the above numerical values, the transmittance of a light is 39% under an illumination of 6500 nit; and the transmittance of a light is 32% under an illumination of 20000 nit.

Based on the analysis of the above experimental data, it can be concluded that by shielding the channel regions of the corresponding two gate electrodes of the thin film transistor with a whole light-shielding layer or separately provided light-shielding layers with a large area, and increasing the area where a side of the first source/drain electrode connected to the pixel electrode is shielded by the light-shielding layer (i.e., when the first via hole structure in the interlayer insulating layer is shielded), occurrence of the leakage current phenomenon of the thin film transistor in the display panel can be reduced. Moreover, the length of the space region shielded at the lower side of the gate line in the first direction X by the light-shielding layer is reduced, so that edges of the light-shielding layer are all contracted into regions covered by the black matrix, thereby the aperture ratio of the display panel may be further improved.

For example, a plurality of thin film transistors may be provided on the first substrate 31, and portions of the light-shielding layer 313 corresponding to different thin film transistors are spaced apart from each other. For example, as shown in FIG. 19, portions of the light-shielding layer 313 corresponding to the first channel region 3121a and the second channel region 3122a of the same thin film transistor are in an integral structure. The light-shielding layer 313 is designed to be in an integral structure, such that the region covered by the light-shielding layer 313 at a side of the first via hole structure 314 is increased, thereby leakage current of the thin film transistor is reduced.

For example, as shown in FIG. 19, both the first branch portion 3121 and the second branch portion 3122 extend in a first direction X, the connection portion 3123 extends in a second direction Y that intersects with the first direction X. The first branch portion 3121, the second branch portion 3122, and the connection portion 3123 surround to form an opening region, at least a part of which is covered by the light-shielding layer 313, such that the whole regions of the first channel region 3121a, the second channel region 3122a, and the first via hole structure 314 can be covered by the light-shielding layer 313, thereby occurrence of leakage current phenomenon in a thin film transistor is reduced, holding capability of pixel capacitance is improved, and the problem of flicker at a low frequency is alleviated. Moreover, aperture ratio of the display panel can also be ensured.

For example, in one embodiment, the first direction X and the second direction Y are perpendicular to each other.

For example, as shown in FIG. 19, the orthographic projections of both side edges of the gate line 3161 in the second direction Y on the base substrate 311 overlap with the orthographic projections of corresponding both side edges of the black matrix 321 in the second direction Y on the base substrate 311, respectively. That is, the orthographic projections of the edge lines on both sides of the gate line 3161 in the second direction Y on the base substrate 311 coincide with the corresponding orthographic projections of the edge lines on both sides of the black matrix 321 in the second direction Y on the base substrate 311, which can ensure that the gate line 3161 can be contracted into the region covered by the black matrix 321, thereby the aperture ratio of the display panel can be further improved.

For example, as shown in FIG. 19, in one embodiment, a gap is provided between the light-shielding layer 313 and the connection portion 3123 in the first direction X (i.e., a gap is provided between the black matrix 321 and the connection portion 3123), so that under the premise that leakage current of thin film transistors comprised in the display panel is reduced, the problem of flicker of the display panel at a low frequency can be alleviated, and the aperture ratio of the display panel can be increased.

For example, as shown in FIG. 19, in one embodiment, the orthographic projection of an edge of the light-shielding layer 313 corresponding to of a portion of the first branch portion 3121 close to the connection portion 3123 on the base substrate 311 overlaps with the orthographic projection of an edge of the black matrix 321 corresponding to a portion of the first branch portion 3121 close to the connection portion 3123 on the base substrate 311. That is, the orthographic projection of the edge of the portion of the light-shielding layer 313 corresponding to the first branch portion 3121 close to the connection portion 3123 on the base substrate 311 and the orthographic projection of the edge of the portion of the black matrix 321 corresponding to the first branch portion 3121 close to the connection portion 3123 on the base substrate 311 are leveling. That is, the orthographic projection of the edge line of the portion of the light-shielding layer 313 corresponding to the first branch portion 3121 close to the connection portion 3123 on the substrate 311 coincides with the orthographic projection of the edge line of the portion of the black matrix 321 corresponding to the first branch portion 3121 close to the connection portion 3123 on the substrate 311, so that the edge of the light-shielding layer 313 can be completely contracted into the region covered by the black matrix 321, thereby the aperture ratio of the display panel is ensured.

For example, in other embodiments, in the second direction Y, the leftmost edge of the light-shielding layer 313 may also coincide with the leftmost edge of the black matrix 321 or may be located within the orthographic projection of the leftmost edge of the black matrix 321 on the base substrate 311. The rightmost edge of the light-shielding layer 313 may also coincide with the leftmost edge of the black matrix 321 or may be located within the orthographic projection of the rightmost edge of the black matrix 321 on the base substrate 311.

For example, as shown in FIG. 19, the orthographic projection of the lowermost edge of the light-shielding layer 313 corresponding to a portion of the first branch portion 3121 positioned below the gate line 3161 in the first direction X overlaps with the orthographic projection of an edge of the black matrix 321 closest to the connection portion 3123 corresponding to a portion of the first branch portion 3121 positioned below the gate line 3161 in the first direction X on the base substrate 311. That is, at least a portion of the black matrix 321 and the edge of the light-shielding layer 313 are also leveling.

For example, FIG. 21 is a schematic diagram of a planar structure of yet another display panel provided by at least one embodiment of the present disclosure, and FIG. 22 is a schematic diagram of a cross-sectional structure of the first substrate in FIG. 21. For example, in combination with FIG. 18, FIG. 21, and FIG. 22, a first substrate 31 comprises a base substrate 311, and a light-shielding layer 313 and a semiconductor layer 312 that are stacked on the base substrate 311. A second substrate 32 comprises a black matrix 321. The semiconductor layer 312 comprises a first branch portion 3121 and a second branch portion 3122 that are provided opposite to each other, and a connection portion 3123 connecting the first branch portion 3121 and the second branch portion 3122. An end of the first branch portion 3121 that is away from the connection portion 3123 corresponds to a first via hole structure 314. That is, the first branch portion 3121 has the first via hole structure 314 on a side of the first branch portion 3121 away from the base substrate 311. The orthographic projection of the first via hole structure 314 on the base substrate 311 is located within the orthographic projection of the end of the first branch portion 3121 away from the connection portion 3123 on the base substrate 311. An end of the second branch portion 3122 away from the connection portion 3123 corresponds to a second via hole structure 315. That is, the second branch portion 3122 has the second via hole structure 315 on a side of the second branch portion 3122 away from the base substrate 311. The orthographic projection of the second via hole structure 315 on the base substrate 311 is located within the orthographic projection of the end of the second branch portion 3122 away from the connection portion 3123 on the base substrate 311. The orthographic projection of the light-shielding layer 313 on the base substrate 311 is located within the orthographic projection of the black matrix 321 on the base substrate 311. The orthographic projections of the first channel region 3121a, the second channel region 3122a, the first via hole structure 314, and the second via hole structure 315 on the base substrate 311 are covered by the orthographic projection of the light-shielding layer 313 on the base substrate 311. Occurrence of leakage current phenomenon can be reduced by the display panel 30 via making all regions of the light-shielding layer 313 be covered by the black matrix 321, and designing the light-shielding layer 313 as such that all regions of the first channel region 3121a, the second channel region 3122a, the first via hole structure 314, and the second via hole structure 315 are covered by the light-shielding layer 313, so that the holding capability of pixel capacitance is improved, thereby the problem of flicker at a low frequency can be alleviated, and the aperture ratio of the display panel can also be ensured.

For example, referring to FIG. 21, in the first direction X, the second via hole structure 315 is farther away from the connection portion 3123 relative to the first via hole structure 314. That is, in the planar view shown in FIG. 21, both the first branch portion 3121 and the second branch portion 3122 are elongated, and extend in the first direction X. The length of the second branch portion 3122 in the first direction X is greater than that of the first branch portion 3121 in the first direction X. That is, in the first direction X, the distance between the second via hole structure 315 and the connection portion 3123 is greater than that between the first via hole structure 314 and the connection portion 3123, such that the second via hole structure 315 corresponding to an end of the second branch portion 3122 and the first via hole structure 314 corresponding to an end of the first branch portion 3121 are not leveling.

For example, in combination with FIG. 21 and FIG. 22, the first substrate 31 further comprises a first metal layer 316 provided on a side of the semiconductor layer 312 away from the base substrate 311. The first metal layer 316 comprises a gate line 3161 extending in the second direction Y. The gate line 3161 is elongated, and comprises a first gate electrode 3161a and a second gate electrode 3161b. The orthographic projection of the first gate electrode 3161a on the base substrate 311 overlaps with the orthographic projection of the first channel region 3121a on the base substrate 311, and the orthographic projection of the second gate electrode 3161b on the base substrate 311 overlaps with the orthographic projection of the second channel region 3122a on the base substrate 311. The orthographic projections of the first gate electrode 3161a and the second gate electrode 3161b on the base substrate 311 are within the orthographic projection of the black matrix 321 on the base substrate 311.

It should be noted that, in the embodiment shown in FIG. 21, a portion at the lower left corner of the connection portion 3123 is covered by the black matrix 321 (i.e., a portion of the connection portion 3123 corresponding to a side of the second branch portion 3122 is covered by the black matrix 321), such that there are two convex portions in the left portion of the black matrix. Moreover, although data line is not shown in FIG. 19, the data line is also covered by the black matrix 321 in an actual product. When a touch signal line is further provided on the display panel, the touch signal line is also covered by the black matrix.

For example, as shown in FIG. 22, a first insulating layer 319 is provided between the light-shielding layer 313 and the semiconductor layer 312; a gate insulating layer 317 is provided between the first insulating layer 319 and the first metal layer 316; and an interlayer insulating layer 318 is provided on a side of the first metal layer 316 away from the base substrate 311.

For example, as shown in FIG. 21 and FIG. 22, the orthographic projection of an edge of the light-shielding layer 313 away from the connection portion 3123 on the substrate 311 comprises a first portion 313c located on a side of the first via hole structure 314 away from the connection portion 3123, and a second portion 313d located on a side of the second via hole structure 315 away from the connection portion 3123. An upper edge of the first portion 313c and an upper edge of the second portion 313d are not on the same straight line. That is, the planar shape of the light-shielding layer 313 is a stepped shape, and the planar shape of the black matrix 321 is a grid shape. Although the planar shape of the black matrix 321 shown in FIG. 21 is rectangular, the planar shape of the corresponding light-shielding layer 313 of the black matrix 321 is also a stepped shape, and in the first direction X, the distance between the first portion 313c and the connection portion 3123 is smaller than that between the second portion 313d and the connection portion 3123. The second portion 313d overlaps with the orthographic projection of the edge of the black matrix 321 located at the upper side of the second via hole structure 315 on the base substrate 311. That is, the second portion 313d coincides with the orthographic projection of the upper edge of the left side of the black matrix 321 corresponding to the second via hole structure 315 on the base substrate 311, and the orthographic projection of the first portion 313c on the base substrate 311 is spaced apart from the orthographic projection of the edge of the black matrix 321 located at the upper side of the first via hole structure 314 on the base substrate 311. The orthographic projection of the second via hole structure 315 on the base substrate 311 is covered by both the orthographic projection of the black matrix 321 on the base substrate 311 and the orthographic projection of the light-shielding layer 313 on the base substrate 311. That is, the orthographic projection of the second via hole structure 315 on the base substrate 311 is located within the orthographic projection of the light-shielding layer 313 on the base substrate 311. It should be noted that, in this embodiment, material of the light-shielding layer 313 is a non-conductive light-shielding material. When the material of the light-shielding layer 313 is a non-conductive light-shielding material, the problem of short circuit between the first source/drain electrode and the second source/drain electrode of the thin film transistor will not occur, even if the phenomenon that the interlayer insulating layer 318 is over-etched to the light-shielding layer 313 occurs.

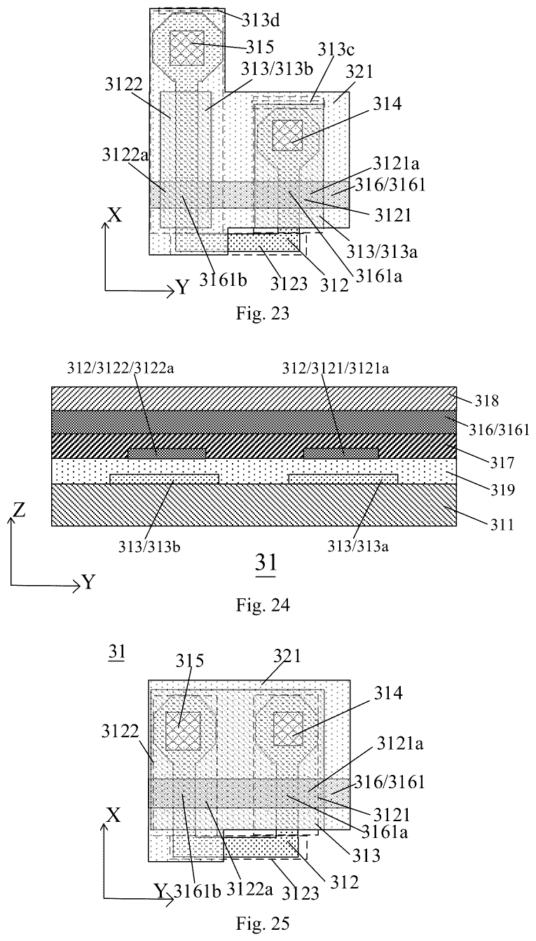

For example, FIG. 23 is a schematic diagram of a planar structure of yet another display panel provided by at least one embodiment of the present disclosure, and FIG. 24 is a schematic diagram of a cross-sectional structure of the first substrate in FIG. 23. For example, in combination with FIG. 18, FIG. 23, and FIG. 24, a first substrate 31 comprises a base substrate 311, and a light-shielding layer 313 and a semiconductor layer 312 that are stacked on the base substrate 311. The second substrate 32 comprises a black matrix 321. The semiconductor layer 312 comprises a first branch portion 3121 and a second branch portion 3122 that are provided opposite to each other, and a connection portion 3123 connecting the first branch portion 3121 and the second branch portion 3122. The first branch portion 3121 comprises a first channel region 3121a, and the second branch portion 3122 comprises a second channel region 3122a. An end of the first branch portion 3121 away from the connection portion 3123 corresponds to the first via hole structure 314. The orthographic projection of the light-shielding layer 313 on the base substrate 311 is located within the orthographic projection of the black matrix 321 on the base substrate 311. Portions of the light-shielding layer 313 corresponding to different thin film transistors are spaced apart from each other, and portions of the light-shielding layer 313 corresponding to the first channel region 3121a and the second channel region 3122a of the same thin film transistor are a first sub light-shielding portion 313a and a second sub light-shielding portion 313b, respectively. The first sub light-shielding portion 313a and the second sub light-shielding portion 313b are spaced apart from each other. The orthographic projections of the first channel region 3121a and the first via hole structure 314 on the base substrate 311 are covered by the first sub-shielding portion 313a, and the orthographic projection of the second channel region 3122a on the base substrate 311, but not the orthographic projection of the second via hole structure 315 on the base substrate 311, is covered by the second sub-shielding portion 313b. Occurrence of leakage current phenomenon can be reduced by the display panel 30 via making all regions of the light-shielding layer 313 and the region between the first sub light-shielding portion 313a and the second sub light-shielding portion 313b be covered by the black matrix 321, and designing the first sub light-shielding portion 313a as such that the orthographic projections of the first channel region 3121a and the first via hole structure 314 on the base substrate 311 is covered by the first sub light-shielding portion 313a, and designing the second sub light-shielding portion 313b as such that the orthographic projection of the second channel region 3122a on the base substrate 311 is covered by the second sub light-shielding portion 313b, so that the holding capability of pixel capacitance is improved, thereby the problem of flicker at a low frequency can be alleviated, and the aperture ratio of the display panel can also be ensured.

For example, referring to FIG. 23, an end of the second branch 3122 away from the connection portion 3123 corresponds to the second via hole structure 315, which is farther away from the connection portion 3123 relative to the first via hole structure 314. That is, in the planar view shown in FIG. 23, both the first branch 3121 and the second branch 3122 are elongated, and extend in the first direction X.

Moreover, the length of the second branch portion 3122 in the first direction X is greater than that of the first branch portion 3121 in the first direction X, i.e., in the first direction X, the distance between the second via hole structure 315 and the connection portion 3123 is greater than that between the first via hole structure 314 and the connection portion 3123, such that the second via hole structure 315 corresponding to the end of the second branch portion 3122 and the first via hole structure 314 corresponding to the end of the first branch portion 3121 are not leveling.

For example, in combination with FIG. 23 and FIG. 24, the first substrate 31 further comprises a first metal layer 316 provided on a side of the semiconductor layer 312 away from the base substrate 311. The first metal layer 316 comprises a gate electrode 3161 extending in the second direction Y. The gate electrode 3161 is elongated, and comprises a first gate electrode 3161a and a second gate electrode 3161b. The orthographic projection of the first gate electrode 3161a on the base substrate 311 overlaps with the orthographic projection of the first channel region 3121a on the base substrate 311, and the orthographic projection of the second gate electrode 3161b on the base substrate 311 overlaps with the orthographic projection of the second channel region 3122a on the base substrate 311. The orthographic projections of the first gate electrode 3161a and the second gate electrode 3161b on the base substrate 311 are within the orthographic projection of the black matrix 321 on the base substrate 311.

It should be noted that in the embodiment shown in FIG. 23, a portion at the lower left corner of the connection portion 3123 is covered by the black matrix 321 (i.e., a portion of the connection portion 3123 corresponding to a side of the second branch portion 3122 is covered by the black matrix 321), such that there are two convex portions in the left portion of the black matrix. Moreover, although data line is not shown in FIG. 19, the data line is also covered by the black matrix 321 in an actual product. When a touch signal line is further provided on the display panel, the touch signal line is also covered by the black matrix.

For example, as shown in FIG. 23, a first insulating layer 319 is provided between the light-shielding layer 313 and the semiconductor layer 312; a gate insulating layer 317 is provided between the first insulating layer 319 and the first metal layer 316; and an interlayer insulating layer 318 is provided on a side of the first metal layer 316 away from the base substrate 311.

For example, as shown in FIG. 23 and FIG. 24, the orthographic projection of an edge of the first sub light-shielding portion 313a away from the connection portion 3123 on the base substrate 311 comprises a first portion 313c located on a side of the first via hole structure 314 away from the connection portion 3123, and the orthographic projection of an edge of the second sub-shielding portion 313b away from the connection portion 3123 on the substrate 311 comprises a second portion 313d located on a side of the second via hole structure 315 away from the connection portion 3123. That is, both the planar shapes of the first sub-shielding portion 313a and the second sub-shielding portion 313b are elongated, and the length of the first sub-shielding portion 313a is smaller than that of the second sub-shielding portion 313b. In the first direction X, the distance between the first portion 313c and the connection portion 3123 is smaller than that between the second portion 313d and the connection portion 3123. The second portion 313d overlaps with the orthographic projection of the edge of the black matrix 321 located at the upper side of the second via hole structure 315 on the base substrate 311. That is, the second portion 313d coincides with the orthographic projection of the edge of the portion of the black matrix 321 located at the upper side of the second via hole structure 315 on the base substrate 311. The first portion 313c is spaced apart from the orthographic projection of an edge of the black matrix 321 located at a portion of an upper side of the first via hole structure 314 on the base substrate 311. The orthographic projection of the second via hole structure 315 on the base substrate 311 is covered by the orthographic projection of the black matrix 321 on the base substrate 311, and the orthographic projection of the second via hole structure 315 on the base substrate 311 is not covered by the orthographic projection of the light-shielding layer 313 on the base substrate 311. That is, the orthographic projection of the second via hole structure 315 on the base substrate 311 is located outside the orthographic projection of the light-shielding layer 313 on the base substrate 311. It should be noted that, in this embodiment, material of the light-shielding layer 313 is a non-conductive light-shielding material or a light-shielding conductive material, the problem of short circuit between the first source/drain electrode and the second source/drain electrode of the thin film transistor will not occur, even if the phenomenon that the interlayer insulating layer 318 is over-etched to the light-shielding layer 313 occurs.

For example, a plurality of thin film transistors are provided on the first substrate 31, and portions of the light-shielding layer 313 corresponding to different thin film transistors are spaced apart from each other. In combination with FIG. 23 and FIG. 24, portions of the light-shielding layer 313 corresponding to the first channel region 3121a and the second channel region 3122a of the same thin film transistor are a first sub light shielding portion 313a and a second sub light shielding portion 313b, respectively. The first sub light shielding portion 313a and the second sub light shielding portion 313b are spaced apart from each other. The orthographic projection of the first channel region 3121a on the base substrate 311 is completely located within the orthographic projection of the first sub light-shielding portion 313a on the base substrate 311, and the orthographic projection of the second channel region 3122a on the base substrate 311 is completely located within the orthographic projection of the second sub light-shielding portion 313b on the base substrate 311. The orthographic projection of the first via hole structure 314 on the base substrate 311 is located within the orthographic projection of the first sub light-shielding portion 313a on the base substrate 311, and the orthographic projection of the second via hole structure 315 on the base substrate 311 is located outside the orthographic projection of the second sub light-shielding portion 313b on the base substrate 311.

For example, as shown in FIG. 23 and FIG. 24, an end of the second branch portion 3122 away from the connection portion 3123 corresponds to the second via hole structure 315. The maximum distance between the second via hole structure 315 and the connection portion 3123 is greater than that between the first via hole structure 314 and the connection portion 3123.

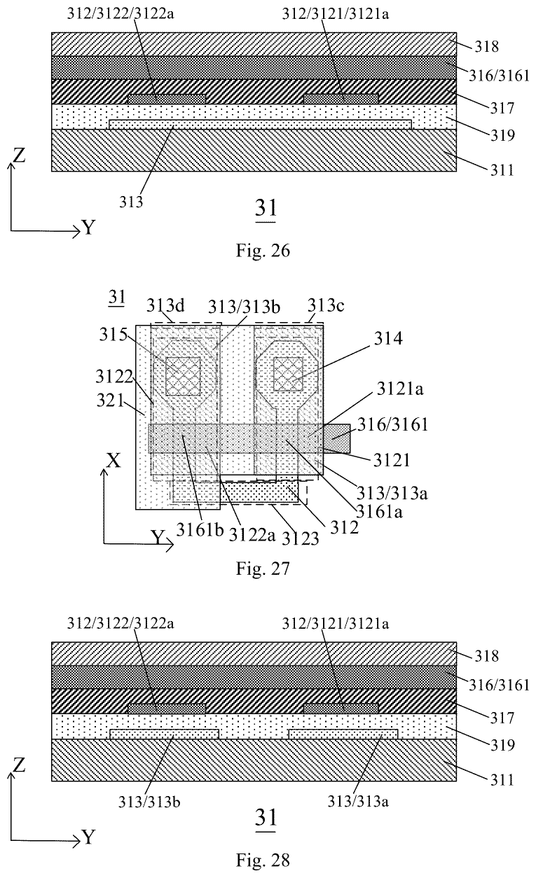

For example, FIG. 25 is a schematic diagram of a planar structure of yet another display panel provided by at least one embodiment of the present disclosure, and FIG. 26 is a schematic diagram of a cross-sectional structure of the first substrate in FIG. 25. For example, in combination with FIG. 18, FIG. 25, and FIG. 26, a first substrate 31 comprises a base substrate 311, and a light-shielding layer 313 and a semiconductor layer 312 that are stacked on the base substrate 311. The second substrate 32 comprises a black matrix 321. The semiconductor layer 312 comprises a first branch portion 3121 and a second branch portion 3122 that are provided opposite to each other, and a connection portion 3123 connecting the first branch portion 3121 and the second branch portion 3122. The first branch portion 3121 comprises a first channel region 3121a, and the second branch portion 3122 comprises a second channel region 3122a. An end of the first branch portion 3121 away from the connection portion 3123 corresponds to the first via hole structure 314, and an end of the second branch portion 3122 away from the connection portion 3123 corresponds to the second via hole structure 315. The orthographic projection of the light-shielding layer 313 on the base substrate 311 is located within the orthographic projection of the black matrix 321 on the base substrate 311, and covers the orthographic projections of the first channel region 3121a, the second channel region 3122a, the first via hole structure 314, and the second via hole structure 315 on the base substrate 311. Occurrence of leakage current phenomenon can be reduced by the display panel 30 via making all regions of the light-shielding layer 313 be covered by the black matrix 321, and designing the light-shielding portion 313 as such that all regions of the first channel region 3121a, the second channel region 3122a, the first via hole structure 314, and the second via hole structure 315 are covered by the light-shielding portion 313, so that the holding capability of pixel capacitance is improved, thereby the problem of flicker at a low frequency can be alleviated, and the aperture ratio of the display panel can also be ensured.

For example, in the schematic diagram of the planar structure shown in FIG. 25, the orthographic projection of the light-shielding layer 313 on the base substrate 311 is located within the orthographic projection of the black matrix 321 on the base substrate 311, and an area of the orthographic projection of the light-shielding layer 313 on the base substrate 311 is smaller than that of the orthographic projection of the black matrix 321 on the base substrate 311. Of course, embodiments of the present disclosure are not limited thereto. The planar shape of the light-shielding layer 313 and the planar shape of the portion corresponding to the black matrix 321 may also be the same, without considering the portion of the black matrix by which the lower left corner portion of the connection portion 3123 is covered.

For example, referring to FIG. 25, an end of the second branch portion 3122 away from the connection portion 3123 corresponds to the second via hole structure 315. In the first direction X, the distance between the second via hole structure 315 and the connection portion 3123 is equal to that between the first via hole structure 314 and the connection portion 3123. That is, in the planar view shown in FIG. 25, both the first branch portion 3121 and the second branch portion 3122 are elongated, and extend in the first direction X. Moreover, the length of the second branch portion 3122 in the first direction X is equal to that of the first branch portion 3121 in the first direction X, such that the second via hole structure 315 corresponding to the end of the second branch portion 3122 and the first via hole structure 314 corresponding to the end of the first branch portion 3121 are leveling.

For example, in combination with FIG. 25 and FIG. 26, the first substrate 31 further comprises a first metal layer 316 provided on a side of the semiconductor layer 312 away from the base substrate 311. The first metal layer 316 comprises a gate electrode 3161 extending in the second direction Y. The gate electrode 3161 is elongated, and comprises a first gate electrode 3161a and a second gate electrode 3161b. The orthographic projection of the first gate electrode 3161a on the base substrate 311 overlaps with the orthographic projection of the first channel region 3121a on the base substrate 311, and the orthographic projection of the second gate electrode 3161b on the base substrate 311 overlaps with the orthographic projection of the second channel region 3122a on the base substrate 311. The orthographic projections of the first gate electrode 3161a and the second gate electrode 3161b on the base substrate 311 are within the orthographic projection of the black matrix 321 on the base substrate 311.

It should be noted that in the embodiment shown in FIG. 25, a portion at the lower left corner of the connection portion 3123 is covered by the black matrix 321 (i.e., a portion of the connection portion 3123 corresponding to a side of the second branch portion 3122 is covered by the black matrix 321), such that there are two convex portions in the left portion of the black matrix. Moreover, although data line is not shown in FIG. 19, the data line is also covered by the black matrix 321 in an actual product. When a touch signal line is further provided on the display panel, the touch signal line is also covered by the black matrix.

For example, as shown in FIG. 26, a first insulating layer 319 is provided between the light-shielding layer 313 and the semiconductor layer 312; a gate insulating layer 317 is provided between the first insulating layer 319 and the first metal layer 316; and an interlayer insulating layer 318 is provided on a side of the first metal layer 316 away from the base substrate 311.

For example, in combination with FIG. 25 and FIG. 26, in one embodiment, material of the light-shielding layer 313 comprises a non-conductive light shielding material. The orthographic projections of the first via hole structure 314 and the second via hole structure 315 on the base substrate 311 are covered by the orthographic projection of the black matrix 321 on the base substrate 311. Both the orthographic projections of the first via hole structure 314 and the second via hole structure 315 on the base substrate 311 is located within the orthographic projection of the light-shielding layer 313 on the substrate 311.

For example, in combination with FIG. 25 and FIG. 26, the light-shielding layer 313 is in an integral structure. The orthographic projection of the first channel region 3121a on the base substrate 311, the orthographic projection of the second channel region 3122a on the base substrate 311, the orthographic projection of the first via hole structure 314 on the base substrate 311, and the orthographic projection of the second via hole structure 315 on the base substrate 311, and also the gap between the first channel region 3121a and the second channel region 3122a, and also the gap between the first via hole structure 314 and the second via hole structure 315 are covered by the orthographic projection of the light-shielding layer 313 on the base substrate 311.

For example, FIG. 27 is a schematic diagram of a planar structure of yet another display panel provided by at least one embodiment of the present disclosure, and FIG. 28 is a schematic diagram of a cross-sectional structure of the first substrate in FIG. 27. For example, in combination with FIG. 18, FIG. 27, and FIG. 28, a first substrate 31 comprises a base substrate 311, and a light-shielding layer 313 and a semiconductor layer 312 that are stacked on the base substrate 311. The second substrate 32 comprises a black matrix 321. The semiconductor layer 312 comprises a first branch portion 3121 and a second branch portion 3122 that are provided opposite to each other, and a connection portion 3123 connecting the first branch portion 3121 and the second branch portion 3122. The first branch portion 3121 comprises a first channel region 3121a, and the second branch portion 3122 comprises a second channel region 3122a. An end of the first branch portion 3121 away from the connection portion 3123 corresponds to a first via hole structure 314. That is, the first branch portion 3121 has the first via hole structure 314 at a side away from the base substrate 311, and the orthographic projection of the first via hole structure 314 on the base substrate 311 is located within the orthographic projection of the end of the first branch portion 3121 away from the connection portion 3123 on the base substrate 311. The orthographic projection of the light-shielding layer 313 on the base substrate 311 is located within the orthographic projection of the black matrix 321 on the base substrate 311. Portions of the light-shielding layer 313 corresponding to different thin film transistors are spaced apart from each other, and portions of the light-shielding layer 313 corresponding to the first channel region 3121a and the second channel region 3122a of the same thin film transistor are a first sub light-shielding portion 313a and a second sub light-shielding portion 313b, respectively. The first sub light-shielding portion 313a and the second sub light-shielding portion 313b are spaced apart from each other. The orthographic projection of the first channel region 3121a and the first via hole structure 314 on the base substrate 311 is covered by the first sub-shielding portion 313a, and the orthographic projections of the second channel region 3122a and the second via hole structure 315 on the base substrate 311 are covered by the second sub light-shielding portion 313b. Occurrence of leakage current phenomenon can be reduced by the display panel 30 via designing the black matrix 321 as such that the first sub light-shielding portion 313a and the second sub light-shielding portion 313b, but not the region between the first sub light-shielding portion 313a and the second sub light-shielding portion 313b, are covered by the black matrix 321, designing the first sub light-shielding portion 313a as such that the orthographic projections of the first channel region 3121a and the first via hole structure 314 on the base substrate 311 are covered by the orthographic projection of the first sub light-shielding portion 313a on the base substrate 311, and designing the second sub light-shielding portion 313b as such that the orthographic projections of the second channel region 3122a and the second via hole structure 315 on the base substrate 311 are covered by the orthographic projection of the second sub light-shielding portion 313b on the base substrate 311, so that the holding capability of pixel capacitance is improved, thereby the problem of flicker at a low frequency can be alleviated, and the aperture ratio of the display panel can also be ensured.

For example, referring to FIG. 27, an end of the second branch portion 3122 away from the connection portion 3123 corresponds to a second via hole structure 315. The distance between the second via hole structure 315 and the connection portion 3123 is equal to that between the first via hole structure 314 and the connection portion 3123. That is, in the planar view shown in FIG. 27, both the first branch portion 3121 and the second branch portion 3122 are elongated, and extend in the first direction X. The length of the second branch portion 3122 in the first direction X is equal to that of the first branch portion 3121 in the first direction X, i.e., in the first direction X, the distance between the second via hole structure 315 and the connection portion 3123 is equal to that between the first via hole structure 314 and the connection portion 3123, such that the second via hole structure 315 corresponding to the end of the second branch portion 3122 and the first via hole structure 314 corresponding to the end of the first branch portion 3121 are leveling.

For example, in combination with FIG. 27 and FIG. 28, the first substrate 31 further comprises a first metal layer 316 provided on a side of the semiconductor layer 312 away from the base substrate 311. The first metal layer 316 comprises a gate electrode 3161 extending in the second direction Y. The gate line 3161 is elongated, and comprises a first gate electrode 3161a and a second gate electrode 3161b. The orthographic projection of the first gate electrode 3161a on the base substrate 311 overlaps with the orthographic projection of the first channel region 3121a on the base substrate 311, and the orthographic projection of the second gate electrode 3161b on the base substrate 311 overlaps with the orthographic projection of the second channel region 3122a on the base substrate 311. The orthographic projection of the gate line 3161 on the base substrate 311 is within the orthographic projection of the black matrix 321 on the base substrate 311. That is, the gate line 3161 are also contracted into the region defined by the black matrix 321, so that the aperture ratio of the display panel is not reduced.

It should be noted that in the embodiment shown in FIG. 27, a portion at the lower left corner of the connection portion 3123 is covered by the black matrix 321 (i.e., a portion of the connection portion 3123 corresponding to a side of the second branch portion 3122 is covered by the black matrix 321), such that there are two convex portions in the left portion of the black matrix. Moreover, although data line is not shown in FIG. 19, the data line is also covered by the black matrix 321 in an actual product. When a touch signal line is further provided on the display panel, the touch signal line is also covered by the black matrix.

For example, as shown in FIG. 28, a first insulating layer 319 is provided between the light-shielding layer 313 and the semiconductor layer 312; a gate insulating layer 317 is provided between the first insulating layer 319 and the first metal layer 316; and an interlayer insulating layer 318 is provided on a side of the first metal layer 316 away from the base substrate 311.

For example, as shown in FIG. 27 and FIG. 28, the orthographic projection of an edge of the first sub light-shielding portion 313a away from the connection portion 3123 on the base substrate 311 comprises a first portion 313c located on a side of the first via hole structure 314 away from the connection portion 3123, and the orthographic projection of an edge of the second sub-shielding portion 313b away from the connection portion 3123 on the substrate 311 comprises a second portion 313d located on a side of the second via hole structure 315 away from the connection portion 3123. An upper edge of the first portion 313c and an upper edge of the second portion 313d are on the same straight line. That is, the planar shape of both the first sub-shielding portion 313a and the second sub-shielding portion 313b is elongated, and the length of the first sub light-shielding portion 313a in the first direction X is equal to that of the second sub light-shielding portion 313b in the first direction X. In the first direction X, the distance between the first portion 313c and the connection portion 3123 is equal to that between the second portion 313d and the connection portion 3123. The second portion 313d overlaps with the orthographic projection of an upper edge of the black matrix 321 located at an upper side of the second via hole structure 315 on the base substrate 311. That is, the second portion 313d coincides with the orthographic projection of the upper edge of the black matrix 321 located at the upper side of the second via hole structure 315 on the base substrate 311, and the first portion 313c coincides with the orthographic projection of the upper edge of the black matrix 321 located at the upper side of the first via hole structure 314 on the base substrate 311. The orthographic projection of the second via hole structure 315 on the base substrate 311 is covered by both the orthographic projection of the black matrix 321 on the base substrate 311 and the orthographic projection of the light-shielding layer 313 on the base substrate 311. That is, the orthographic projection of the second via hole structure 315 on the base substrate 311 is located within the orthographic projection of the light-shielding layer 313 on the base substrate 311. It should be noted that, in this embodiment, material of the light-shielding layer 313 is a non-conductive light-shielding material, and the problem of short circuit between the first source/drain electrode and the second source/drain electrode of the thin film transistor will not occur, even if the phenomenon that the interlayer insulating layer 318 is over-etched to the light-shielding layer 313 occurs.

For example, a plurality of thin film transistors are provided on the first substrate 31, and portions of the light-shielding layer 313 corresponding to different thin film transistors are spaced apart from each other. In combination with FIG. 27 and FIG. 28, portions of the light-shielding layer 313 corresponding to the first channel region 3121a and the second channel region 3122a of the same thin film transistor are a first sub light shielding portion 313a and a second sub light shielding portion 313b, respectively. The first sub light shielding portion 313a and the second sub light shielding portion 313b are spaced apart from each other. The orthographic projection of the first channel region 3121a on the base substrate 311 is completely located within the orthographic projection of the first sub light-shielding portion 313a on the base substrate 311, and the orthographic projection of the second channel region 3122a on the base substrate 311 is completely located within the orthographic projection of the second sub light-shielding portion 313b on the base substrate 311. The orthographic projection of the first via hole structure 314 on the base substrate 311 is located within the orthographic projection of the first sub light-shielding portion 313a on the base substrate 311, and the orthographic projection of the second via hole structure 315 on the base substrate 311 is located within the orthographic projection of the second sub light-shielding portion 313b on the base substrate 311.

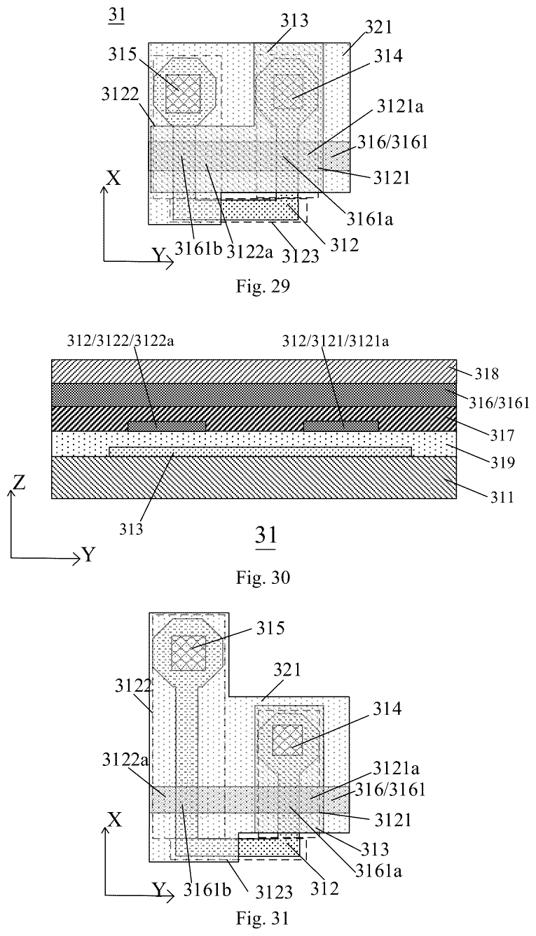

For example, FIG. 29 is a schematic diagram of a planar structure of yet another display panel provided by at least one embodiment of the present disclosure, and FIG. 30 is a schematic diagram of a cross-sectional structure of the first substrate shown in FIG. 29. In combination with FIG. 18, FIG. 29, and FIG. 30, a first substrate 31 comprises a base substrate 311, and a light-shielding layer 313 and a semiconductor layer 312 that are stacked on the base substrate 311. The second substrate 32 comprises a black matrix 321. The semiconductor layer 312 comprises a first branch portion 3121 and a second branch portion 3122 that are provided opposite to each other, and a connection portion 3123 connecting the first branch portion 3121 and the second branch portion 3122. The first branch portion 3121 comprises a first channel region 3121a, and the second branch portion 3122 comprises a second channel region 3122a. An end of the first branch portion 3121 away from the connection portion 3123 corresponds to the first via hole structure 314. That is, the first branch portion 3121 has the first via hole structure 314 at a side away from the base substrate 311, and the orthographic projection of the first via hole structure 314 on the base substrate 311 is located within the orthographic projection of the end of the first branch portion 3121 away from the connection portion 3123 on the base substrate 311. An end of the second branch portion 3122 away from the connection portion 3123 corresponds to the second via hole structure 315. That is, the second branch portion 3122 has the second via hole structure 315 at a side away from the base substrate 311, and the orthographic projection of the second via hole structure 315 on the base substrate 311 is located within the orthographic projection of the end of the second branch portion 3122 away from the connection portion 3123 on the base substrate 311. The orthographic projection of the light-shielding layer 313 on the base substrate 311 is located within the orthographic projection of the black matrix 321 on the base substrate 311. The orthographic projections of the first channel region 3121a, the second channel region 3122a, and the first via hole structure 2126 on the base substrate 311 are covered by the orthographic projection of the light-shielding layer 313 on the base substrate 311. Occurrence of leakage current phenomenon can be reduced by the display panel 30 by making all regions of the first channel region 3121a, the second channel region 3122a, and the first via hole structure 314 are covered by the light-shielding layer 213, so that the holding capability of pixel capacitance is improved, thereby the problem of flicker at a low frequency can be alleviated, and the aperture ratio of the display panel can also be ensured.

For example, as shown in FIG. 29, in the first direction X, the distance between the second via hole structure 315 and the connection portion 3123 is equal to that between the first via hole structure 314 and the connection portion 3123. That is, in the planar view shown in FIG. 29, both the first branch portion 3121 and the second branch portion 3122 are elongated, and extend in the first direction X. The length of the second branch portion 3122 in the first direction X is equal to that of the first branch portion 3121 in the first direction X, such that the second via hole structure 315 corresponding to the end of the second branch portion 3122 and the first via hole structure 2124 corresponding to the end of the first branch portion 3121 are leveling.

For example, as shown in FIG. 29 and FIG. 30, the first substrate 31 further comprises a first metal layer 316 provided on a side of the semiconductor layer 312 away from the base substrate 311. The first metal layer 316 comprises a gate line 3161 extending in the second direction Y. The gate line 3161 is elongated, and comprises a first gate electrode 3161a and a second gate electrode 3161b. The orthographic projection of the first gate electrode 3161a on the base substrate 311 overlaps with the orthographic projection of the first channel region 3121a on the base substrate 311, and the orthographic projection of the second gate electrode 3161b on the base substrate 311 overlaps with the orthographic projection of the second channel region 3122a on the base substrate 311.

For example, the first gate electrode 3161a, the second gate electrode 3161b, and the gate line 3161 are in an integral linear structure. The first gate electrode 3161a and the second gate electrode 3161b are portions of the gate line 3161. The first gate electrode 3161a is a portion of the gate line 3161 corresponding to the first channel region 3121a. The second gate electrode 3161b is a portion of the gate line 3161 corresponding to the second channel region 3122a.

It should be noted that in the embodiment shown in FIG. 29, a portion at the lower left corner of the connection portion 3123 is covered by the black matrix 321 (i.e., a portion of the connection portion 3123 corresponding to a side of the second branch portion 3122 is covered by the black matrix 321), such that there are two convex portions in the left portion of the black matrix. Moreover, although data line is not shown in FIG. 19, the data line is also covered by the black matrix 321 in an actual product. When a touch signal line is further provided on the display panel, the touch signal line is also covered by the black matrix.

For example, as shown in FIG. 30, a first insulating layer 319 is provided between the light-shielding layer 313 and the semiconductor layer 312; a gate insulating layer 317 is provided between the first insulating layer 319 and the first metal layer 316; and an interlayer insulating layer 318 is provided on a side of the first metal layer 316 away from the base substrate 311.

For example, in combination with FIG. 29 and FIG. 30, in one embodiment, material of the light-shielding layer 313 comprises a non-conductive light shielding material or a conductive light shielding material. The orthographic projection of the first via hole structure 314 on the base substrate 311 is located within the orthographic projection of the light-shielding layer 313 on the base substrate 311.

For example, in combination with FIG. 29 and FIG. 30, the light-shielding layer 313 is in an integral structure. The orthographic projection of the first channel region 3121a on the base substrate 311, the orthographic projection of the second channel region 3122a on the base substrate 311, the orthographic projection of the first via hole structure 314 on the base substrate 311, and also the gap between the first channel region 3121a and the second channel region 3122a, are covered by the orthographic projection of the light-shielding layer 313 on the base substrate 311. The planar shape of the light-shielding layer 313 is stepped.

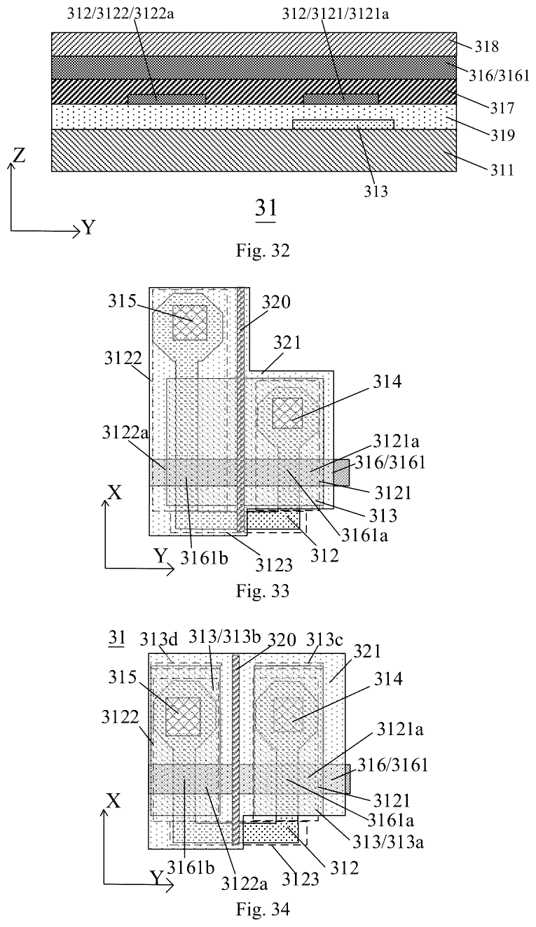

For example, FIG. 31 is a schematic diagram of a planar structure of yet another display panel provided by at least one embodiment of the present disclosure, and FIG. 32 is a schematic diagram of a cross-sectional structure of the first substrate shown in FIG. 31. In combination with FIG. 18, FIG. 31, and FIG. 32, a first substrate 31 comprises a base substrate 311, and a light-shielding layer 313 and a semiconductor layer 312 that are stacked on the base substrate 311. The second substrate 32 comprises a black matrix 321. The semiconductor layer 312 comprises a first branch portion 3121 and a second branch portion 3122 that are provided opposite to each other, and a connection portion 3123 connecting the first branch portion 3121 and the second branch portion 3122. The first branch portion 3121 comprises a first channel region 3121a, and the second branch portion 3122 comprises a second channel region 3122a. An end of the first branch portion 3121 away from the connection portion 3123 corresponds to the first via hole structure 314. That is, the first branch portion 3121 has the first via hole structure 314 at a side away from the base substrate 311, and the orthographic projection of the first via hole structure 314 on the base substrate 311 is located within the orthographic projection of the end of the first branch portion 3121 away from the connection portion 3123 on the base substrate 311. An end of the second branch portion 3122 away from the connection portion 3123 corresponds to the second via hole structure 315. That is, the second branch portion 3122 has the second via hole structure 315 at a side away from the base substrate 311, and the orthographic projection of the second via hole structure 315 on the base substrate 311 is located within the orthographic projection of the end of the second branch portion 3122 away from the connection portion 3123 on the base substrate 311. The orthographic projection of the light-shielding layer 313 on the base substrate 311 is located within the orthographic projection of the black matrix 321 on the base substrate 311. The orthographic projections of the first channel region 3121a and the first via hole structure 2126 on the base substrate 311 are covered by the orthographic projection of the light-shielding layer 313 on the base substrate 311. Occurrence of leakage current phenomenon can be reduced by the display panel 30 by making that all regions of the first channel region 3121a and the first via hole structure 314 are covered by the light-shielding layer 213, so that the holding capability of pixel capacitance is improved, thereby the problem of flicker at a low frequency can be alleviated, and the aperture ratio of the display panel can also be ensured.

For example, as shown in FIG. 31, in the first direction X, the distance between the second via hole structure 315 and the connection portion 3123 is greater than that between the first via hole structure 314 and the connection portion 3123.

For example, as shown in FIG. 31 and FIG. 32, the first substrate 31 further comprises a first metal layer 316 provided on a side of the semiconductor layer 312 away from the base substrate 311. The first metal layer 316 comprises a gate line 3161 extending in the second direction Y. The gate line 3161 is elongated, and comprises a first gate electrode 3161a and a second gate electrode 3161b. The orthographic projection of the first gate electrode 3161a on the base substrate 311 overlaps with the orthographic projection of the first channel region 3121a on the base substrate 311, and the orthographic projection of the second gate electrode 3161b on the base substrate 311 overlaps with the orthographic projection of the second channel region 3122a on the base substrate 311.

It should be noted that in the embodiment shown in FIG. 31, a portion at the lower left corner of the connection portion 3123 is covered by the black matrix 321, that is, a portion of the connection portion 3123 corresponding to a side of the second branch portion 3122 is covered by the black matrix 321, such that there are two convex portions in the left portion of the black matrix. Moreover, although data line is not shown in FIG. 19, the data line is also covered by the black matrix 321 in an actual product. When a touch signal line is further provided on the display panel, the touch signal line is also covered by the black matrix.

For example, as shown in FIG. 32, a first insulating layer 319 is provided between the light-shielding layer 313 and the semiconductor layer 312; a gate insulating layer 317 is provided between the first insulating layer 319 and the first metal layer 316; and an interlayer insulating layer 318 is provided on a side of the first metal layer 316 away from the base substrate 311.

For example, in combination with FIG. 31 and FIG. 32, in one embodiment, material of the light-shielding layer 313 comprises a non-conductive light shielding material or a conductive light shielding material. The orthographic projection of the first via hole structure 314 on the base substrate 311 is located within the orthographic projection of the light-shielding layer 313 on the base substrate 311.

For example, FIG. 33 is a schematic diagram of a planar structure of yet another display panel provided by at least one embodiment of the present disclosure. The display panel shown in FIG. 33 is different from the display panel shown in FIG. 19 only in that a touch signal line 320 extending along the first direction X is provided between the first branch portions 3121 and the second branch portions 3122. Such a design can save space for placing traces, so that the display panel is thinner and lighter. The structure of the display panel shown in FIG. 33 may refer to the related description of the display panel shown in FIG. 19, and is not repeated herein.

For example, in the structure shown in FIG. 33, the touch signal line 320 is also covered by the black matrix 321.

For example, FIG. 34 is a schematic diagram of a stacked structure of yet another display panel provided by at least one embodiment of the present disclosure. The display panel shown in FIG. 34 is different from the display panel shown in FIG. 27 only in that a touch signal line 320 extending along the first direction X is provided between the first branch portions 3121 and the second branch portions 3122. Such a design can save space for placing traces, so that the display panel is thinner and lighter. The structure of the display panel shown in FIG. 34 may refer to the related description of the display panel shown in FIG. 27, and is not repeated here.

For example, in the structure shown in FIG. 34, the touch signal line 320 is also covered by the black matrix 321.

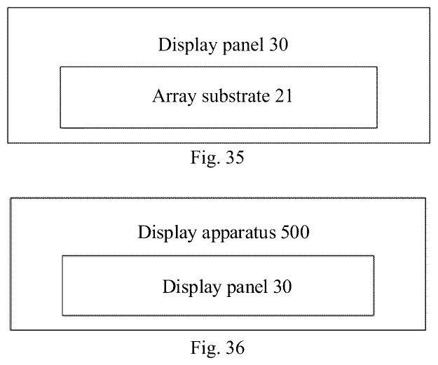

For example, FIG. 35 is a block diagram of a display panel provided by at least one embodiment of the present disclosure. As shown in FIG. 35, the display panel 30 comprises the array substrate 21, that is the first substrate 31 in any of the embodiments described above. In one embodiment, the display panel 30 further comprises a liquid crystal layer sandwiched between the first substrate 31 and the second substrate 32. Other circuit structures included in the display panel may refer to conventional designs, which are not limited in the embodiments of the present disclosure.

At least one embodiment of the present disclosure also provides a display apparatus. For example, FIG. 36 is a block diagram of a display apparatus provided by at least one embodiment of the present disclosure. As shown in FIG. 36, a display apparatus 500 comprises the display panel 30 described in any embodiment of the above, and the display panel 30 comprises the array substrate provided in any one of the above embodiments.

For example, the display apparatus 500 may be a display apparatus having a display function. For example, the display apparatus 500 may be any product or component having a display function and a touch function, such as a display, an OLED display panel, an OLED TV, a liquid crystal display panel, a liquid crystal display TV, a QLED display panel, a QLED TV, an electronic paper, a mobile phone, a tablet computer, a notebook computer, a digital photo frame, a navigator, etc.

The array substrate, the display panel and the display apparatus provided in at least one embodiment of the present disclosure have at least one of the following beneficial technical effects:
(1) Leakage current of the display panel can be reduced by the array substrate provided in at least one embodiment of the present disclosure by adjusting design of the light-shielding layer to shield the first via hole structure, so that holding capability of pixel capacitance is improved, thereby the problem of flicker at a low frequency can be alleviated, and aperture ratio of the display panel can also be ensured.
(2) In the display panel provided in at least one embodiment of the present disclosure, the light-shielding layer is designed as a whole, and the gap portion between the first branch portion and the second branch portion is completely shielded by the light-shielding layer. That is, sufficient shielding of the light-shielding layer to the gap portions above the gate line is achieved. Leakage current of the thin film transistor can be reduced without affecting the aperture ratio.
(3) In the display panel provided in at least one embodiment of the present disclosure, the edges of the light-shielding layer are all contracted into the region covered by the black matrix, so that the aperture ratio of the display panel can be further improved.

The following points need to be explained:
(1) The drawings of the embodiment of the present disclosure only relate to the structure related to the embodiment of the present disclosure, and other structures can refer to the general design.
(2) For the sake of clarity, in the drawings used to describe the embodiments of the present disclosure, the thickness of layers or regions is enlarged or reduced, that is, these drawings are not drawn to actual scale.
(3) In the case of no conflict, the embodiments of the present disclosure and the features in the embodiments can be combined with each other to obtain a new embodiment.

The above is only the specific implementation of the present disclosure, but the scope of protection of the present disclosure is not limited thereto, and the scope of protection of the present disclosure should be subject to the scope of protection of the claims.

1. An array substrate, comprising: a base substrate, and a semiconductor layer and a light-shielding layer that are stacked on the base substrate, wherein the semiconductor layer comprises a first branch portion and a second branch portion that are provided opposite to each other, and a connection portion connecting the first branch portion and the second branch portion; the first branch portion comprises a first channel region, and the second branch portion comprises a second channel region; a first via hole structure is provided on a side of the first branch portion away from the base substrate, and an orthographic projection of the first via hole structure on the base substrate is located within an orthographic projection of an end of the first branch portion away from the connection portion on the base substrate; and an orthographic projection of the light-shielding layer on the base substrate at least covers orthographic projections of the first channel region and the first via hole structure on the base substrate.

2. The array substrate according to claim 1, wherein a second via hole structure is provided on a side of the second branch portion away from the base substrate, an orthographic projection of the second via hole structure on the base substrate is located within an orthographic projection of an end of the second branch portion away from the connection portion on the base substrate, and a minimum distance between the second via hole structure and the connection portion is greater than or equal to a minimum distance between the first via hole structure and the connection portion.

3. The array substrate according to claim 2, wherein the orthographic projection of the second via hole structure on the base substrate is located outside the orthographic projection of the light-shielding layer on the base substrate.

4. The array substrate according to claim 1, wherein a plurality of thin film transistors are provided on the base substrate, portions of the light-shielding layer corresponding to different thin film transistors are spaced apart from each other, and portions of the light-shielding layer corresponding to the first channel region and the second channel region of a same thin film transistor are in an integral structure.

5. The array substrate according to claim 4, wherein both the first branch portion and the second branch portion extend in a first direction, the connection portion extends in a second direction that intersects the first direction, the first branch portion, the second branch portion, and the connection portion surround to form an opening region, at least a part of the opening region is covered by the light-shielding layer.

6. The array substrate according to claim 1, further comprising a first metal layer provided on a side of the semiconductor layer away from the base substrate, the first metal layer comprises a gate line extending in the second direction, the gate line comprises a first gate electrode and a second gate electrode, an orthographic projection of the first gate electrode on the base substrate overlaps with an orthographic projection of the first channel region on the base substrate, and an orthographic projection of the second gate electrode on the base substrate overlaps with an orthographic projection of the second channel region on the base substrate.

7. The array substrate according to claim 5, wherein there is a gap between the light-shielding layer and the connection portion in the first direction.

8. The array substrate according to claim 2, wherein a plurality of thin film transistors are provided on the base substrate, portions of the light-shielding layer corresponding to different thin film transistors are spaced apart from each other, portions of the light-shielding layer corresponding to the first channel region and the second channel region of a same thin film transistor are a first sub light-shielding portion and a second sub light-shielding portion, respectively, and the first sub light-shielding portion and the second sub light-shielding portion are spaced apart from each other.

9. The array substrate according to claim 8, wherein the orthographic projection of the first via hole structure on the base substrate is located within an orthographic projection of the first sub light-shielding portion on the base substrate, and an orthographic projection of the second via hole structure second via hole structure on the base substrate is located outside an orthographic projection of the second sub light-shielding portion on the base substrate.

10. A display panel, comprising a first substrate and a second substrate that are provided opposite to each other, wherein
the first substrate comprises a base substrate, and a semiconductor layer and a light-shielding layer that are stacked on the base substrate;
the second substrate comprises a black matrix;
the semiconductor layer comprises a first branch portion and a second branch portion that are provided opposite to each other, and a connection portion connecting the first branch portion and the second branch portion; the first branch portion comprises a first channel region, and the second branch portion comprises a second channel region; a first via hole structure is provided on a side of the first branch portion away from the base substrate, and an orthographic projection of the first via hole structure on the base substrate is located within an orthographic projection of an end of the first branch portion away from the connection portion on the base substrate; and
an orthographic projection of the light-shielding layer on the base substrate is located within an orthographic projection of the black matrix on the base substrate, and at least covers the orthographic projections of the first channel region and the first via hole structure on the base substrate.

11. The display panel according to claim 10, wherein an end of the second branch portion away from the connection portion corresponds to a second via hole structure, and the second via hole structure is farther away from the connection portion relative to the first via hole structure.

12. The display panel according to claim 11, wherein a material of the light-shielding layer comprises a conductive metal, the orthographic projection of the second via hole structure on the base substrate is covered by the orthographic projection of the black matrix on the base substrate, and the orthographic projection of the second via hole structure on the base substrate is located outside the orthographic projection of the light-shielding layer on the base substrate.

13. The display panel according to claim 10, wherein a plurality of thin film transistors are provided on the first substrate, portions of the light-shielding layer corresponding to different thin film transistors are spaced apart from each other, and portions of the light-shielding layer corresponding to the first channel region and the second channel region of a same thin film transistor are in an integral structure.

14. The display panel according to claim 13, wherein both the first branch portion and the second branch portion extend in a first direction, the connection portion extends in a second direction that intersects with the first direction, and the first branch portion, the second branch portion, and the connection portion surround to form an opening region, at least a part of the opening region is covered by the light-shielding layer.

15. The display panel according to claim 10, wherein the first substrate further comprises a first metal layer provided on a side of the semiconductor layer away from the base substrate, the first metal layer comprises a gate line extending in the second direction, and the gate line comprises a first gate electrode and a second gate electrode, an orthographic projection of the first gate electrode on the base substrate overlaps with an orthographic projection of the first channel region on the base substrate, and an orthographic projection of the second gate electrode on the base substrate overlaps with an orthographic projection of the second channel region on the base substrate.

16. The display panel according to claim 15, wherein the orthographic projection of the first gate electrode on the base substrate is within the orthographic projection of the black matrix on the base substrate, and the orthographic projection of the second gate electrode on the base substrate is within the orthographic projection of the black matrix on the base substrate.

17. The display panel according to claim 16, wherein there is a gap between the light-shielding layer and the connection portion in the first direction.

18. The display panel according to claim 14, wherein an orthographic projection of an edge of the light-shielding layer corresponding to a portion of the first branching portion close to the connection portion on the base substrate overlaps with an orthographic projection of an edge of the black matrix corresponding to a portion of the first branching portion close to the connection portion on the base substrate.

19. The display panel according to claim 11, wherein an orthographic projection of an edge of the light-shielding layer corresponding to a portion of the first branching portion farthest away from the connection portion on the base substrate overlaps with an orthographic projection of an edge of the black matrix corresponding to a portion of the first branching portion farthest away from the connection portion on the base substrate.

20-25. (canceled)

26. A display apparatus, comprising the array substrate according to claim 1.
